(19) United States
(12) Patent Application Publication
(10) Pub. No.: US 2024/0199895 A1
(43) Pub. Date: Jun. 20, 2024

(54) COMPOSITION, FILM, OPTICAL FILTER, OPTICAL SENSOR, AND IMAGE DISPLAY DEVICE

(71) Applicant: FUJIFILM Corporation, Tokyo (JP)

(72) Inventors: Hirotaka TAKISHITA, Haibara-gun (JP); Yoshinori Taguchi, Haibara-gun (JP)

(73) Assignee: FUJIFILM Corporation, Tokyo (JP)

(21) Appl. No.: 18/438,727

(22) Filed: Feb. 12, 2024

Related U.S. Application Data
(63) Continuation of application No. PCT/JP22/30852, filed on Aug. 15, 2022.

(30) Foreign Application Priority Data
Aug. 19, 2021 (JP) 2021-133930

(51) Int. Cl. C09D 5/32; C08L 33/06; C08L 35/02; C09D 4/06; C09D 7/45; C09D 7/65

(52) U.S. Cl. CPC C09D 5/32; C08L 33/066; C08L 35/02; C09D 4/06; C09D 7/45; C09D 7/65

(57) ABSTRACT

Provided are a composition containing a cyclic siloxane compound, a silicone-based surfactant other than the cyclic siloxane compound, and a curable compound, in which a content of the cyclic siloxane compound is 0.01 to 10 parts by mass with respect to 100 parts by mass of the silicone-based surfactant; a film formed of the composition; an optical filter; an optical sensor; and an image display device.

### CROSS-REFERENCE TO RELATED APPLICATIONS

This application is a Continuation of PCT International Application No. PCT/JP2022/030852 filed on Aug. 15, 2022, which claims priority under 35 U.S.C § 119(a) to Japanese Patent Application No. 2021-133930 filed on Aug. 19, 2021. Each of the above application(s) is hereby expressly incorporated by reference, in its entirety, into the present application.

### BACKGROUND OF THE INVENTION

### 1. Field of the Invention

The present invention relates to a composition containing a silicone-based surfactant.

In addition, the present invention relates to a film, an optical filter, an optical sensor, and an image display device.

### 2. Description of the Related Art

As a composition used for manufacturing an optical filter such as a color filter, a composition containing a surfactant has been used.

As the surfactant, a silicone-based surfactant or the like has been known. JP2007-186683A discloses that dimethylpolysiloxane having polyalkylene oxide is used as the surfactant.

### SUMMARY OF THE INVENTION

In recent years, further improvement in performance has been desired for a film used in the optical filter or the like. As one of the required characteristics, it is required to suppress variation in spectral characteristics in a high-temperature and high-humidity environment at a higher level.

Accordingly, an object of the present invention is to provide a composition capable of forming a film in which variation in spectral characteristics is suppressed in a high-temperature and high-humidity environment. Another object of the present invention is to provide a film, an optical filter, an optical sensor, and an image display device.

The present invention provides the following.
<1> A composition comprising:
a cyclic siloxane compound;
a silicone-based surfactant other than the cyclic siloxane compound; and
a curable compound,
in which a content of the cyclic siloxane compound is 0.01 to 10 parts by mass with respect to 100 parts by mass of the silicone-based surfactant.
<2> The composition according to <1>,
in which the cyclic siloxane compound is a compound represented by Formula (1),

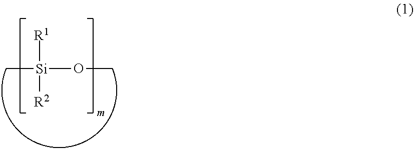

in Formula (1), R¹ and R² each independently represent a hydrogen atom or a substituent, and m represents an integer of 3 to 20.
<3> The composition according to <1> or <2>,
in which the cyclic siloxane compound includes at least one selected from octamethylcyclotetrasiloxane, decamethylcyclopentasiloxane, or dodecamethylcyclohexasiloxane.
<4> A composition comprising:
a cyclic siloxane compound;
a silicone-based surfactant other than the cyclic siloxane compound; and
a curable compound,
in which the cyclic siloxane compound is at least one selected from octamethylcyclotetrasiloxane, decamethylcyclopentasiloxane, or dodecamethylcyclohexasiloxane, and
a content of the cyclic siloxane compound is 0.01 to 10 parts by mass with respect to 100 parts by mass of the silicone-based surfactant.
<5> The composition according to any one of <1> to <4>,
in which the composition contains two or more kinds of the cyclic siloxane compounds.
<6> The composition according to any one of <1> to <5>,
in which a content of the silicone-based surfactant in the composition is 1 to 2,000 ppm by mass.
<7> The composition according to any one of <1> to <6>,
in which the curable compound contains a resin and a polymerizable monomer, and
the composition further contains a photopolymerization initiator.
<8> The composition according to any one of <1> to <7>, further comprising: a coloring material.
<9> A film formed of the composition according to any one of <1> to <8>.
<10> An optical filter comprising:
the film according to <9>.
<11> An optical sensor comprising:
the film according to <9>.
<12> An image display device comprising:
the film according to <9>.

According to the present invention, it is possible to provide a composition capable of forming a film in which variation in spectral characteristics is suppressed in a high-temperature and high-humidity environment. In addition, according to the present invention, it is possible to provide a film in which variation in spectral characteristics is suppressed in a high-temperature and high-humidity environment, an optical filter, an optical sensor, and an image display device.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by an excimer laser, an extreme ultraviolet ray (EUV light), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, near-infrared rays denote light having a wavelength in a range of 700 to 2500 nm.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a coloring material which is hardly dissolved in a solvent.

In the present specification, the term “step” denotes not only an individual step but also a step which is not clearly distinguishable from another step as long as an effect expected from the step can be achieved.

### <Composition>

A first aspect of the composition according to the embodiment of the present invention is:
a composition containing a cyclic siloxane compound, a silicone-based surfactant other than the cyclic siloxane compound, and a curable compound,
in which a content of the cyclic siloxane compound is 0.01 to 10 parts by mass with respect to 100 parts by mass of the silicone-based surfactant.

In addition, a second aspect of the composition according to the embodiment of the present invention is:
a composition containing a cyclic siloxane compound, a silicone-based surfactant other than the cyclic siloxane compound, and a curable compound,
in which the cyclic siloxane compound is at least one selected from octamethylcyclotetrasiloxane, decamethylcyclopentasiloxane, or dodecamethylcyclohexasiloxane, and
a content of the cyclic siloxane compound is 0.01 to 10 parts by mass with respect to 100 parts by mass of the silicone-based surfactant.

With the composition according to the embodiment of the present invention, it is possible to form a film in which variation in spectral characteristics is suppressed in a high-temperature and high-humidity environment. The reason for obtaining such an effect is presumed as follows. Since the composition according to the embodiment of the present invention contains the cyclic siloxane compound, it is presumed that the cyclic siloxane compound can suppress phase separation between a component derived from the curable compound and the silicone-based surfactant in the film. Since the content of the cyclic siloxane compound is 0.01 to 10 parts by mass with respect to 100 parts by mass of the silicone-based surfactant, it is presumed that the cyclic siloxane compound itself does not undergo phase separation, and can act on the silicone-based surfactant. Therefore, it is presumed that, even in a case where the film is exposed to a high-temperature and high-humidity environment, the phase separation between the component derived from the curable compound and the silicone-based surfactant can be suppressed. Accordingly, it is presumed that the composition according to the embodiment of the present invention is capable of forming a film in which variation in spectral characteristics is suppressed in a high-temperature and high-humidity environment.

The composition according to the embodiment of the present invention is preferably used as a composition for an optical sensor or an image display device. More specifically, the composition according to the embodiment of the present invention can be preferably used as a composition for forming an optical filter used in an optical sensor or an image display device. Examples of the optical filter include a color filter, a near-infrared transmitting filter, and a near-infrared cut filter, and a color filter is preferable.

Examples of the color filter include a filter having a colored pixel which transmits light having a specific wavelength, and a filter having at least one colored pixel selected from a red pixel, a blue pixel, a green pixel, a yellow pixel, a cyan pixel, or a magenta pixel is preferable. The color filter can be formed of a composition containing a chromatic coloring material. The color filter may further have a pixel other than the colored pixels, such as a transparent pixel.

Examples of the near-infrared cut filter include a filter having a maximal absorption wavelength in a wavelength range of 700 to 1800 nm. The maximal absorption wavelength of the near-infrared cut filter is preferably in a wavelength range of 700 to 1300 nm and more preferably in a wavelength range of 700 to 1100 nm. In addition, in the near-infrared cut filter, a transmittance of in the entire wavelength range of 400 to 650 nm is preferably 70% or more, more preferably 80% or more, and still more preferably 90% or more. In addition, the transmittance at at least one point in a wavelength range of 700 to 1800 nm is preferably 20% or less. In addition, in the near-infrared cut filter, absorbance Amax/absorbance A550, which is a ratio of an absorbance Amax at a maximal absorption wavelength to an absorbance A550 at a wavelength of 550 nm, is preferably 20 to 500, more preferably 50 to 500, still more preferably 70 to 450, and particularly preferably 100 to 400. The near-infrared cut filter can be formed of a composition containing a near-infrared absorbing coloring material.

The near-infrared transmitting filter is a filter which transmits at least a part of near-infrared rays. As the near-infrared transmitting filter, a filter which shields at least a part of visible light and transmits at least a part of near-infrared rays is preferable. Preferred examples of the near-infrared transmitting filter include filters satisfying spectral characteristics in which the maximum value of a transmittance in a wavelength range of 400 to 640 nm is 20% or less (preferably 15% or less and more preferably 10% or less) and the minimum value of a transmittance in a wavelength range of 1100 to 1300 nm is 70% or more (preferably 75% or more and more preferably 80% or more). The near-infrared transmitting filter is preferably a filter which satisfies any one of the following spectral characteristics (1) to (5).
(1): filter in which the maximum value of a transmittance in a wavelength range of 400 to 640 nm is 20% or less (preferably 15% or less and more preferably 10% or less) and the minimum value of a transmittance in a wavelength range of 800 to 1500 nm is 70% or more (preferably 75% or more and more preferably 80% or more).
(2): filter in which the maximum value of a transmittance in a wavelength range of 400 to 750 nm is 20% or less (preferably 15% or less and more preferably 10% or less) and the minimum value of a transmittance in a wavelength range of 900 to 1500 nm is 70% or more (preferably 75% or more and more preferably 80% or more).
(3): filter in which the maximum value of a transmittance in a wavelength range of 400 to 830 nm is 20% or less (preferably 15% or less and more preferably 10% or less) and the minimum value of a transmittance in a wavelength range of 1000 to 1500 nm is 70% or more (preferably 75% or more and more preferably 80% or more).
(4): filter in which the maximum value of a transmittance in a wavelength range of 400 to 950 nm is 20% or less (preferably 15% or less and more preferably 10% or less) and the minimum value of a transmittance in a wavelength range of 1100 to 1500 nm is 70% or more (preferably 75% or more and more preferably 80% or more).
(5): filter in which the maximum value of a transmittance in a wavelength range of 400 to 1050 nm is 20% or less (preferably 15% or less and more preferably 10% or less) and the minimum value of a transmittance in a wavelength range of 1200 to 1500 nm is 70% or more (preferably 75% or more and more preferably 80% or more).

The composition according to the embodiment of the present invention can also be used as a composition for forming a light shielding film. In a case where the composition according to the embodiment of the present invention is used as a composition for forming a light shielding film, the composition according to the embodiment of the present invention preferably contains a black coloring material as a coloring material, and more preferably contains a black pigment.

In a case where the composition according to the embodiment of the present invention is used as a composition for forming a light shielding film, an optical density (OD) of a film formed of the composition according to the embodiment of the present invention per film thickness of 1.5 m in a wavelength range of 400 to 1100 nm is preferably 2.5 or more and more preferably 3.0 or more. In addition, the upper limit value thereof is not particularly limited, but is preferably 10 or less, in general. In the present specification, the expression that the optical density per film thickness of 1.5 m in a wavelength range of 400 to 1100 nm is 2.5 or more means that an optical density per film thickness of 1.5 m in the entire wavelength range of 400 to 1100 nm is 2.5 or more.

In addition, reflectivity of the above-described film is preferably less than 8%, more preferably less than 6%, and still more preferably less than 4%. The lower limit is preferably 0% or more. The reflectivity is determined from a reflectivity spectrum obtained by injecting light having a wavelength of 400 to 1100 nm at an incidence angle of 5° using a spectroscope V7200 (trade name) VAR unit manufactured by JASCO Corporation. Specifically, the reflectivity of light having a wavelength which exhibits the maximum reflectivity in a wavelength range of 400 to 1100 nm is taken as the reflectivity of the film.

The composition according to the embodiment of the present invention is also preferably a composition used for forming a pattern in a photolithography method. According to this aspect, finely sized pixels can be easily formed. For example, a composition containing a component having an ethylenically unsaturated bond-containing group (for example, a resin having an ethylenically unsaturated bond-containing group or a monomer having an ethylenically unsaturated bond-containing group) and a photopolymerization initiator can be preferably used as a composition used for forming a pattern in a photolithography method. The composition for forming a pattern in the photolithography method preferably further contains an alkali-soluble resin.

A concentration of solid contents of the composition according to the embodiment of the present invention is preferably 5% to 30% by mass. The lower limit is preferably 7.5% by mass or more and more preferably 10% by mass or more. The upper limit is preferably 25% by mass or less and more preferably 20% by mass or less.

Hereinafter, each of the components used in the composition according to the embodiment of the present invention will be described.

### <<Cyclic Siloxane Compound>>

The composition according to the embodiment of the present invention contains a cyclic siloxane compound. Here, the cyclic siloxane compound refers to a cyclic compound formed by a siloxane bond.

The cyclic siloxane compound is preferably a compound represented by Formula (1).

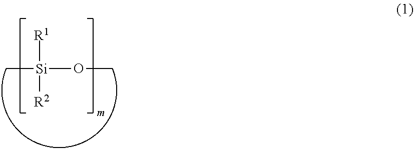

In Formula (1), R¹ and R² each independently represent a hydrogen atom or a substituent, and m represents an integer of 3 to 20.

Examples of the substituent represented by R¹ and R² in Formula (1) include an alkyl group and an aryl group, and an alkyl group is preferable.

The number of carbon atoms in the alkyl group is preferably 1 to 10, more preferably 1 to 5, still more preferably 1 to 3, and particularly preferably 1. The alkyl group may be linear, branched, or cyclic, but is preferably linear.

The number of carbon atoms in the aryl group is preferably 6 to 20, more preferably 6 to 12, and particularly preferably 6.

R¹ and R² are each preferably a hydrogen atom, a methyl group, or a phenyl group, and more preferably a methyl group.

m in Formula (1) represents an integer of 3 to 20, and is preferably an integer of 3 to 10, more preferably an integer of 3 to 8, still more preferably an integer of 3 to 6, and particularly preferably an integer of 4 to 6.

A molecular weight of the cyclic siloxane compound is preferably 1,000 or less, more preferably 800 or less, and still more preferably 600 or less. The lower limit can be 100 or more.

Specific examples of the cyclic siloxane compound include octamethylcyclotetrasiloxane, decamethylcyclopentasiloxane, dodecamethylcyclohexasiloxane, and hexamethylcyclotrisiloxane, and at least one selected from octamethylcyclotetrasiloxane, decamethylcyclopentasiloxane, or dodecamethylcyclohexasiloxane is preferable.

The composition according to the embodiment of the present invention may contain only one kind of cyclic siloxane compound, but it is preferable that the composition according to the embodiment of the present invention contains two or more kinds of cyclic siloxane compounds. In a case of containing two or more kinds of cyclic siloxane compounds, it is preferable to contain a compound in which m in Formula (1) is 3 or 4 (preferably, m is 4) and a compound in which m in Formula (1) is an integer of 5 or more (preferably, a compound in which m is an integer of 5 to 10, more preferably, a compound in which m is an integer of 5 to 8, and still more preferably, a compound in which m is 5 or 6). In addition, as a proportion of the compound in which m in Formula (1) is 3 or 4 and the compound in which m in Formula (1) is an integer of 5 or more, a content of the compound in which m in Formula (1) is an integer of 5 or more is preferably 10 to 1000 parts by mass, more preferably 25 to 750 parts by mass, and still more preferably 50 to 500 parts by mass with respect to 100 parts by mass of the compound in which m in Formula (1) is 3 or 4.

The cyclic siloxane compound preferably includes at least one selected from octamethylcyclotetrasiloxane, decamethylcyclopentasiloxane, or dodecamethylcyclohexasiloxane, and more preferably includes octamethylcyclotetrasiloxane, decamethylcyclopentasiloxane, and dodecamethylcyclohexasiloxane.

In addition, the cyclic siloxane compound is preferably at least one selected from octamethylcyclotetrasiloxane, decamethylcyclopentasiloxane, or dodecamethylcyclohexasiloxane, and more preferably consists of octamethylcyclotetrasiloxane, decamethylcyclopentasiloxane, and dodecamethylcyclohexasiloxane.

In a case where a cyclic siloxane compound including octamethylcyclotetrasiloxane, decamethylcyclopentasiloxane, and dodecamethylcyclohexasiloxane is used, a proportion of the octamethylcyclotetrasiloxane, decamethylcyclopentasiloxane, and dodecamethylcyclohexasiloxane is preferably 1 to 100 parts by mass of octamethylcyclotetrasiloxane and 50 to 200 parts by mass of decamethylcyclopentasiloxane with respect to 100 parts by mass of dodecamethylcyclohexasiloxane. The octamethylcyclotetrasiloxane is preferably 1 to 100 parts by mass and more preferably 10 to 50 parts by mass with respect to 100 parts by mass of the dodecamethylcyclohexasiloxane. The decamethylcyclopentasiloxane is preferably 1 to 200 parts by mass and more preferably 50 to 150 parts by mass with respect to 100 parts by mass of the dodecamethylcyclohexasiloxane.

The content of the cyclic siloxane compound is 0.01 to 10 parts by mass with respect to 100 parts by mass of the silicone-based surfactant. The lower limit is preferably 0.1 parts by mass or more and more preferably 0.5 parts by mass or more. The upper limit is preferably 5 parts by mass or less, more preferably 4 parts by mass or less, and more preferably 3 parts by mass or less.

In addition, the total content of the octamethylcyclotetrasiloxane, decamethylcyclopentasiloxane, and dodecamethylcyclohexasiloxane is preferably 0.01 to 10 parts by mass with respect to 100 parts by mass of the silicone-based surfactant. The lower limit is preferably 0.1 parts by mass or more and more preferably 0.5 parts by mass or more. The upper limit is preferably 5 parts by mass or less, more preferably 4 parts by mass or less, and more preferably 3 parts by mass or less.

In addition, the content of the octamethylcyclotetrasiloxane is preferably 0.01 to 10 parts by mass with respect to 100 parts by mass of the silicone-based surfactant. The lower limit is preferably 0.03 parts by mass or more, more preferably 0.05 parts by mass or more, still more preferably 0.1 parts by mass or more, and even preferably 0.5 parts by mass or more. The upper limit is preferably 5 parts by mass or less, more preferably 4 parts by mass or less, and more preferably 3 parts by mass or less.

In addition, the content of the decamethylcyclopentasiloxane is preferably 0.01 to 10 parts by mass with respect to 100 parts by mass of the silicone-based surfactant. The lower limit is preferably 0.03 parts by mass or more, more preferably 0.05 parts by mass or more, still more preferably 0.1 parts by mass or more, and even preferably 0.5 parts by mass or more. The upper limit is preferably 5 parts by mass or less, more preferably 4 parts by mass or less, and more preferably 3 parts by mass or less.

In addition, the content of the dodecamethylcyclohexasiloxane is preferably 0.01 to 10 parts by mass with respect to 100 parts by mass of the silicone-based surfactant. The lower limit is preferably 0.03 parts by mass or more, more preferably 0.05 parts by mass or more, still more preferably 0.1 parts by mass or more, and even preferably 0.5 parts by mass or more. The upper limit is preferably 5 parts by mass or less, more preferably 4 parts by mass or less, and more preferably 3 parts by mass or less.

In a case where the composition according to the embodiment of the present invention contains two or more kinds of cyclic siloxane compounds, it is preferable that the total amount thereof is within the above-described range.

### <<Silicone-Based Surfactant>>

The composition according to the embodiment of the present invention contains a silicone-based surfactant other than the cyclic siloxane compound. The silicone-based surfactant is preferably a compound which does not include a fluorine atom. In the present specification, the silicone-based surfactant is a compound having a repeating unit including a siloxane bond in the main chain, and is a compound including a hydrophobic part and a hydrophilic part in one molecule.

A viscosity of the silicone-based surfactant at 25° C. is preferably 40 mm²/s or less, more preferably 38 mm²/s or less, and still more preferably 36 mm²/s or less. In a case where the viscosity of the silicone-based surfactant is 40 mm²/s or less, a surface condition during application is excellent. From the reason that a certain amount of chain length is required in order to function as a surfactant, the lower limit of the viscosity of the silicone-based surfactant is preferably 10 mm²/s or more, more preferably 15 mm²/s or more, still more preferably 20 mm²/s or more, and particularly preferably 25 mm²/s or more.

A hydroxyl number of the silicone-based surfactant is preferably 80 mgKOH/g or more, more preferably 90 mgKOH/g or more, still more preferably 100 mgKOH/g or more, and particularly preferably 110 mgKOH/g or more. In a case where the hydroxyl number of the silicone-based surfactant is 80 mgKOH/g or more, the effects of the present invention are more remarkably exhibited. The upper limit of the hydroxyl number of the silicone-based surfactant is preferably 200 mgKOH/g or less, more preferably 150 mgKOH/g or less, and still more preferably 130 mgKOH/g or less.

The silicone-based surfactant is preferably modified polysiloxane. Examples of the modified polysiloxane include compounds having a structure in which a substituent is introduced into a side chain and/or a terminal of polysiloxane. Examples of the substituent include a group having a functional group selected from an amino group, an epoxy group, an alicyclic epoxy group, a hydroxy group, a mercapto group, a carboxy group, a fatty acid ester group, and a fatty acid amide group, and a group having a polyether chain; and a group having a hydroxy group is preferable and a group having an alkyleneoxy group and a hydroxy group is more preferable.

The group having a hydroxy group is preferably a group represented by Formula (G-1) or a group represented by (G-2).

-L^{G1}-(ORG1)ₘ₁OH (G-1)

-L^{G1}-(R^{G1}O)ₘ₁H (G-2)

In Formula (G-1) and Formula (G-2), L^{G1} represents a single bond or a divalent linking group. Examples of the divalent linking group represented by L^{G1} include an alkylene group (preferably an alkylene group having 1 to 12 carbon atoms and more preferably an alkylene group having 1 to 6 carbon atoms), an arylene group (preferably an arylene group having 6 to 20 carbon atoms and more preferably an arylene group having 6 to 12 carbon atoms), —NH—, —SO—, —SO₂—, —CO—, —O—, —COO—, —OCO—, —S—, and a group including a combination of two or more thereof.

In Formula (G-1) and Formula (G-2), m1 represents 0 or an integer of 1 or more, and is preferably an integer of 1 to 5 and more preferably an integer of 1 to 3.

In Formula (G-1) and Formula (G-2), R^{G1} represents an alkylene group. The number of carbon atoms in the alkylene group is preferably 1 to 10, more preferably 1 to 5, still more preferably 1 to 3, and particularly preferably 2 or 3. The alkylene group represented by R^{G1} may be linear or branched. The alkylene groups represented by m1 pieces of R^{G1}'S may be the same or different from each other.

Examples of the group including a polyether chain include a group represented by Formula (G-11) and a group represented by Formula (G-12).

-L^{G11}-(R^{G11}O)ₘ₂R^{G12} (G-11)

-L^{G11}-(OR^{G11}O)ₘ₂OR^{G12} (G-12)

In Formula (G-11) and Formula (G-12), L^{G11} represents a single bond or a divalent linking group. Examples of the divalent linking group represented by L^{G11} include an alkylene group (preferably an alkylene group having 1 to 12 carbon atoms and more preferably an alkylene group having 1 to 6 carbon atoms), an arylene group (preferably an arylene group having 6 to 20 carbon atoms and more preferably an arylene group having 6 to 12 carbon atoms), —NH—, —SO—, —SO₂—, —CO—, —O—, —COO—, —OCO—, —S—, and a group including a combination of two or more thereof.

In Formula (G-11) and Formula (G-12), m2 represents a number of 2 or more, and is preferably 2 to 200.

In Formula (G-11) and Formula (G-12), R^{G11} represents an alkylene group. The number of carbon atoms in the alkylene group is preferably 1 to 10, more preferably 1 to 5, still more preferably 1 to 3, and particularly preferably 2 or 3. The alkylene group represented by R^{G11} may be linear or branched. The alkylene groups represented by m2 pieces of R^{G11}'s may be the same or different from each other.

In Formula (G-11) and Formula (G-12), R^{G12} represents an alkyl group or an aryl group. The number of carbon atoms in the alkyl group represented by R^{G12} is preferably 1 to 10, more preferably 1 to 5, and still more preferably 1 to 3. The alkyl group may be linear or branched. The number of carbon atoms in the aryl group represented by R^{G12} is preferably 6 to 20 and more preferably 6 to 10.

The silicone-based surfactant is preferably a carbinol-modified polysiloxane and more preferably a carbinol-modified dialkyl polysiloxane. In addition, the silicone-based surfactant is preferably dimethyl polysiloxane having an alkyleneoxy group and a hydroxy group.

The silicone-based surfactant is preferably a compound represented by Formula (Si-1) or Formula (Si-2).

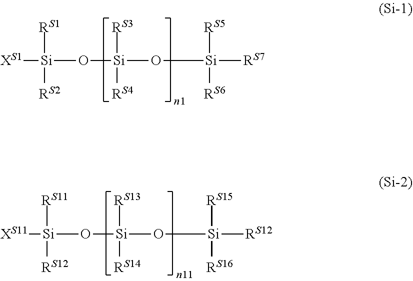

In Formula (Si-1), R^{S1} to R^{S7} each independently represent an alkyl group or an aryl group,
X^{S1} represents the group represented by Formula (G-1) or group represented by Formula (G-2) described above, and
n1 represents a number of 2 to 200.

In Formula (Si-2), R^{S11} to R^{S16} each independently represent an alkyl group or an aryl group,
X^{S11} and X^{S12} each independently represent the group represented by Formula (G-1) or group represented by Formula (G-2) described above, and
n11 represents a number of 2 to 200.

The number of carbon atoms in the alkyl group represented by R^{S1} to R^{S7} in Formula (Si-1) and in the alkyl group represented by R^{S11} to R^{S16} in Formula (Si-2) is preferably 1 to 10, more preferably 1 to 5, still more preferably 1 to 3, and particularly preferably 1. The alkyl group may be linear, branched, or cyclic, but is preferably linear.

The number of carbon atoms in the aryl group represented by R^{S1} to R^{S7} in Formula (Si-1) and in the aryl group represented by R^{S11} to R^{S16} in Formula (Si-2) is preferably 6 to 20, more preferably 6 to 12, and particularly preferably 6.

R^{S1} to R^{S7} and R^{S11} to R^{S16} are preferably a methyl group or a phenyl group and more preferably a methyl group.

Specific examples of the silicone-based surfactant include a compounds having the following structure.

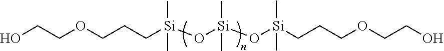

Examples of a commercially available product of the silicone-based surfactant include: DC3PA, SH7PA, DC11PA, SH21PA, SH28PA, SH29PA, SH30PA, SH8400, SH 8400 FLUID, FZ-2122, 67 Additive, 74 Additive, M Additive, and SF 8419 OIL (all of which are manufactured by Dow-TORAY); TSF-4300, TSF-4445, TSF-4460, and TSF-4452 (all of which are manufactured by Momentive Performance Materials Inc.); KP-341, KF-6000, KF-6001, KF-6002, and KF-6003 (all of which are manufactured by Shin-Etsu Chemical Co., Ltd.); and BYK-307, BYK-322, BYK-323, BYK-330, BYK-333, BYK-3760, and BYK-UV3510 (all of which are manufactured by BYK Chemie).

A content of the silicone-based surfactant in the composition is preferably 1 to 2,000 ppm by mass. The lower limit is preferably 3 ppm by mass or more and more preferably 5 ppm by mass or more. The upper limit is preferably 1,000 ppm by mass or less and more preferably 500 ppm by mass or less.

### <<Other Surfactants>>

The composition according to the embodiment of the present invention may contain a surfactant other than the silicone-based surfactant (hereinafter, also referred to as other surfactants). Examples of the other surfactants include a fluorine-based surfactant, a nonionic surfactant, a cationic surfactant, and an anionic surfactant.

Examples of the fluorine-based surfactant include surfactants described in paragraphs 0060 to 0064 of JP2014-041318A (paragraphs 0060 to 0064 of the corresponding WO2014/017669A) and the like, surfactants described in paragraphs 0117 to 0132 of JP2011-132503A, and surfactants described in JP2020-008634A, the contents of which are incorporated herein by reference. Examples of a commercially available product of the fluorine-based surfactant include: MEGAFACE F-171, F-172, F-173, F-176, F-177, F-141, F-142, F-143, F-144, F-437, F-475, F-477, F-479, F-482, F-554, F-555-A, F-556, F-557, F-558, F-559, F-560, F-561, F-565, F-563, F-568, F-575, F-780, EXP, MFS-330, R-01, R-40, R-40-LM, R-41, R-41-LM, RS-43, R-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 208G, 215M, 245F, 601AD, 601ADH2, 602A, 610FM, 710FL, 710FM, 710FS, and FTX-218 (all of which are manufactured by NEOS COMPANY LIMITED).

As the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

It is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

As the fluorine-based surfactant, a block polymer can also be used. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraphs 0016 to 0037 of JP2010-032698A, or the following compounds are also exemplified as the fluorine-based surfactant used in the present invention.

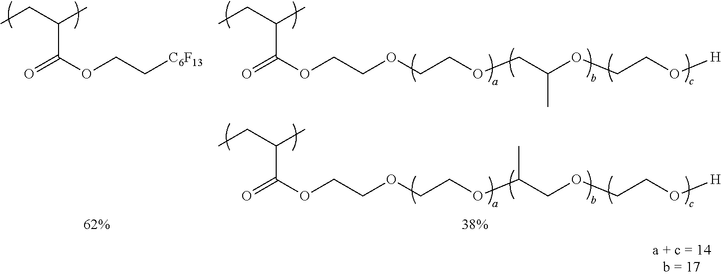

A weight-average molecular weight of the compound is preferably 3,000 to 50,000 and, for example, 14,000. In the compound, “%” representing the proportion of a repeating unit is mol %.

In addition, as the fluorine-based surfactant, a fluorine-containing polymer having an ethylenically unsaturated bond-containing group at a side chain can also be used. Specific examples thereof include compounds described in paragraphs 0050 to 0090 and paragraphs 0289 to 0295 of JP2010-164965A, and MEGAFACE RS-101, RS-102, RS-718K, and RS-72-K manufactured by DIC Corporation. In addition, as the fluorine-based surfactant, a compound described in paragraphs 0015 to 0158 of JP2015-117327A can also be used.

In addition, from the viewpoint of environmental regulation, it is also preferable to use a surfactant described in WO2020/084854A as a substitute for the surfactant having a perfluoroalkyl group having 6 or more carbon atoms.

In addition, it is also preferable to use a fluorine-containing imide salt compound represented by Formula (fi-1) as the surfactant.

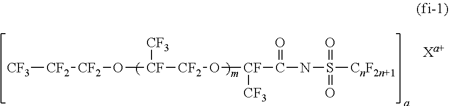

In Formula (fi-1), m represents 1 or 2, n represents an integer of 1 to 4, a represents 1 or 2, and X^{a+} represents an a-valent metal ion, a primary ammonium ion, a secondary ammonium ion, a tertiary ammonium ion, a quaternary ammonium ion, or NH₄⁺.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 1OR5, 17R2, and 25R2 (manufactured by BASF SE), TETRONIC 304, 701, 704, 901, 904, and 150R1 (manufactured by BASF SE), SOLSPERSE 20000 (manufactured by Lubrizol Japan Ltd.), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the cationic surfactant include a tetraalkylammonium salt, an alkylamine salt, a benzalkonium salt, an alkylpyridium salt, and an imidazolium salt. Specific examples thereof include dihydroxyethylstearylamine, 2-heptadecenyl-hydroxyethylimidazoline, lauryldimethylbenzylammonium chloride, cetylpyridinium chloride, and stealamidemethylpyridium chloride.

Examples of the anionic surfactant include dodecylbenzene sulfonic acid, sodium dodecylbenzene sulfonate, sodium lauryl sulfate, sodium alkyldiphenyl ether disulfonate, sodium alkylnaphthalene sulfonate, sodium dialkyl sulfosuccinate, sodium stearate, potassium oleate, sodium dioctyl sulfosuccinate, sodium polyoxyethylene alkyl ether sulfate, sodium polyoxyethylene alkylphenyl ether sulfate, sodium dialkyl sulfosuccinate, sodium stearate, sodium oleate, and sodium t-octylphenoxyethoxypolyethoxyethyl sulfate.

A content of the other surfactants in the composition is preferably 1000 ppm by mass or less, more preferably 500 ppm by mass or less, and still more preferably 100 ppm by mass or less. It is also preferable that the composition according to the embodiment of the present invention does not contain the other surfactants.

### <<Curable Compound>>

The composition according to the embodiment of the present invention contains a curable compound. Examples of the curable compound include a polymerizable compound and a resin. The resin may be a non-polymerizable resin (resin not having a polymerizable group), or may be a polymerizable resin (resin having a polymerizable group). Examples of the polymerizable group include an ethylenically unsaturated bond-containing group and a cyclic ether group. Examples of the ethylenically unsaturated bond-containing group include a vinyl group, a (meth)allyl group, and a (meth)acryloyl group. Examples of the cyclic ether group include an epoxy group and an oxetanyl group, and an epoxy group is preferable. The epoxy group may be an alicyclic epoxy group. The alicyclic epoxy group means a monovalent functional group having a cyclic structure, in which an epoxy ring and a saturated hydrocarbon ring are fused.

It is preferable that the curable compound contains at least a resin. In addition, in a case where the composition according to the embodiment of the present invention is used as a composition for photolithography, it is preferable to use a resin (preferably, a resin having an acid group) as a curable compound and a polymerizable monomer (monomer-type polymerizable compound), and it is more preferable to use a resin (preferably, a resin having an acid group) and a polymerizable monomer (monomer-type polymerizable compound) having an ethylenically unsaturated bond-containing group.

### (Polymerizable Compound)

Examples of the polymerizable compound include a compound having an ethylenically unsaturated bond-containing group and a compound having a cyclic ether group. The compound having an ethylenically unsaturated bond-containing group can be preferably used as a radically polymerizable compound. In addition, the compound having a cyclic ether group can be preferably used as a cationically polymerizable compound.

Examples of a resin-type polymerizable compound include a resin which includes a repeating unit having a polymerizable group.

A molecular weight of the monomer-type polymerizable compound (polymerizable monomer) is preferably less than 2,000 and more preferably 1,500 or less. The lower limit of the molecular weight of the polymerizable monomer is preferably 100 or more and more preferably 200 or more. A weight-average molecular weight (Mw) of the resin-type polymerizable compound is preferably 2,000 to 2,000,000. The upper limit of the weight-average molecular weight is preferably 1,000,000 or less and more preferably 500,000 or less. The lower limit of the weight-average molecular weight is preferably 3,000 or more and more preferably 5,000 or more.

The compound having an ethylenically unsaturated bond-containing group as the polymerizable monomer is preferably a trifunctional to pentadecafunctional (meth)acrylate compound and more preferably a trifunctional to hexafunctional (meth)acrylate compound. Specific examples thereof include compounds described in paragraphs 0095 to 0108 of JP2009-288705A, paragraph 0227 of JP2013-029760A, paragraphs 0254 to 0257 of JP2008-292970A, paragraphs 0034 to 0038 of JP2013-253224A, paragraph 0477 of JP2012-208494A, JP2017-048367A, JP6057891B, JP6031807B, and JP2017-194662A, the contents of which are incorporated herein by reference.

Examples of the compound having an ethylenically unsaturated bond-containing group include dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), and a compound having a structure in which a (meth)acryloyl group of these compounds is bonded through an ethylene glycol and/or a propylene glycol residue (for example, SR454 and SR499 which are commercially available products from Sartomer Company Inc.). In addition, as the compound having an ethylenically unsaturated bond-containing group, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-AO (manufactured by KYOEISHA CHEMICAL Co., Ltd.), and the like can also be used.

In addition, as the compound having an ethylenically unsaturated bond-containing group, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

The compound having an ethylenically unsaturated bond-containing group may further have an acid group such as a carboxy group, a sulfo group, and a phosphoric acid group. Examples of a commercially available product of such a compound include ARONIX M-305, M-510, M-520, and ARONIX TO-2349 (manufactured by TOAGOSEI CO., LTD.).

As the compound having an ethylenically unsaturated bond-containing group, a compound having a caprolactone structure can also be used. With regard to the compound having a caprolactone structure, reference can be made to the description in paragraphs 0042 to 0045 of JP2013-253224A, the content of which is incorporated herein by reference. Examples of the compound having a caprolactone structure include DPCA-20, DPCA-30, DPCA-60, and DPCA-120, each of which is commercially available as series from Nippon Kayaku Co., Ltd.

As the compound having an ethylenically unsaturated bond-containing group, a compound having an ethylenically unsaturated bond-containing group and an alkyleneoxy group can also be used. Such a compound is preferably a compound having an ethylenically unsaturated bond-containing group and an ethyleneoxy group and/or a propyleneoxy group, more preferably a compound having an ethylenically unsaturated bond-containing group and an ethyleneoxy group, and still more preferably a 3- to 6-functional (meth)acrylate compound having 4 to 20 ethyleneoxy groups. Examples of a commercially available product thereof include SR-494 manufactured by Sartomer Company Inc., which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the compound having an ethylenically unsaturated bond-containing group, a polymerizable compound having a fluorene skeleton can also be used. Examples of a commercially available product thereof include OGSOL EA-0200 and EA-0300 (manufactured by Osaka Gas Chemicals Co., Ltd., (meth)acrylate monomer having a fluorene skeleton).

As the compound having an ethylenically unsaturated bond-containing group, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

As the compound having an ethylenically unsaturated bond-containing group, it is also preferable to use UA-7200 (manufactured by Shin-Nakamura Chemical Co., Ltd.), DPHA-40H (manufactured by Nippon Kayaku Co., Ltd.), UA-306H, UA-306T, UA-306I, AH-600, T-600, AI-600, and LINC-202UA (manufactured by KYOEISHA CHEMICAL Co., Ltd.), 8UH-1006 and 8UH-1012 (all of which are manufactured by Taisei Fine Chemical Co., Ltd.), Light Acrylate POB-AO (manufactured by KYOEISHA CHEMICAL Co., Ltd.), and the like.

Examples of the compound having a cyclic ether group include a compound having an epoxy group and a compound having an oxetanyl group, and a compound having an epoxy group is preferable. Examples of the compound having an epoxy group include a compound having 1 to 100 epoxy groups in one molecule. The upper limit of the number of epoxy groups may be, for example, 10 or less or 5 or less. The lower limit of the number of epoxy groups is preferably 2 or more.

The compound having a cyclic ether group may be a low-molecular-weight compound (for example, having a molecular weight of less than 1,000) or a high-molecular-weight compound (macromolecule) (for example, having a molecular weight of 1,000 or more, and in a case of a polymer, having a weight-average molecular weight of 1,000 or more). The weight-average molecular weight of the cyclic ether group is preferably 200 to 100,000 and more preferably 500 to 50,000. The upper limit of the weight-average molecular weight is preferably 10,000 or less, more preferably 5,000 or less, and still more preferably 3,000 or less.

As the compound having a cyclic ether group, the compounds described in paragraphs 0034 to 0036 of JP2013-011869A, the compounds described in paragraphs 0147 to 0156 of JP2014-043556A, the compounds paragraphs 0085 to 0092 of JP2014-089408A, and the compounds described in JP2017-179172A can also be used.

Examples of a commercially available product of the compound having a cyclic ether group include DENACOL EX-212L, EX-212, EX-214L, EX-214, EX-216L, EX-216, EX-321L, EX-321, EX-850L, and EX-850 (all of which are manufactured by Nagase ChemteX Corporation); ADEKA RESIN EP-4000S, EP-4003S, EP-4010S, and EP-4011S (all of which are manufactured by ADEKA Corporation); NC-2000, NC-3000, NC-7300, XD-1000, EPPN-501, and EPPN-502 (all of which are manufactured by ADEKA Corporation); CELLOXIDE 2021P, CELLOXIDE 2081, CELLOXIDE 2083, CELLOXIDE 2085, EHPE3150, EPOLEAD PB 3600, and PB 4700 (all of which are manufactured by Daicel Corporation); CYCLOMER P ACA 200M, ACA 230AA, ACA Z250, ACA Z251, ACA Z300, and ACA Z320 (all of which are manufactured by Daicel Corporation); jER 1031S, jER 157S65, jER 152, jER 154, and jER 157S70 (all of which are manufactured by Mitsubishi Chemical Corporation); ARON OXETANE OXT-121, OXT-221, OX-SQ, and PNOX (all of which are manufactured by TOAGOSEI CO., LTD.); ADEKA GLYCILOL ED-505 (manufactured by ADEKA Corporation, epoxy group-containing monomer); MARPROOF G-0150M, G-0105SA, G-0130SP, G-0250SP, G-1005S, G-1005SA, G-1010S, G-2050M, G-01100, and G-01758 (manufactured by NOF Corporation, epoxy group-containing polymer); OXT-101, OXT-121, OXT-212, and OXT-221 (all of which are manufactured by TOAGOSEI CO., LTD., oxetanyl group-containing monomer); and OXE-10 and OXE-30 (both of which are manufactured by OSAKA ORGANIC CHEMICAL INDUSTRY LTD., oxetanyl group-containing monomer).

### (Resin)

A resin can be used as the curable compound in the composition according to the embodiment of the present invention. It is preferable that the curable compound contains at least a resin. The resin is blended in, for example, an application for dispersing a pigment or the like in the composition or an application as a binder. Mainly, a resin which is used for dispersing a pigment or the like in the composition is also referred to as a dispersant. However, such applications of the resin are merely exemplary, and the resin can also be used for other purposes in addition to such applications. A resin having a polymerizable group also corresponds to the polymerizable compound.

A weight-average molecular weight of the resin is preferably 3,000 to 2,000,000. The upper limit is preferably 1,000,000 or less and more preferably 500,000 or less. The lower limit is preferably 4,000 or more and more preferably 5,000 or more.

Examples of the resin include a (meth)acrylic resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide resin, a polyamideimide resin, a polyolefin resin, a cyclic olefin resin, a polyester resin, a styrene resin, a vinyl acetate resin, a polyvinyl alcohol resin, a polyvinyl acetal resin, a polyurethane resin, and a polyurea resin. These resins may be used singly or as a mixture of two or more kinds thereof. From the viewpoint of improving heat resistance, as the cyclic olefin resin, a norbornene resin is preferable. Examples of a commercially available product of the norbornene resin include ARTON series (for example, ARTON F4520) manufactured by JSR Corporation. In addition, as the resin, resins described in Examples of WO2016/088645A, resins described in JP2017-057265A, resins described in JP2017-032685A, resins described in JP2017-075248A, resins described in JP2017-066240A, resins described in JP2017-167513A, resins described in JP2017-173787A, resins described in paragraphs 0041 to 0060 of JP2017-206689A, resins paragraphs 0022 to 0071 of JP2018-010856A, block polyisocyanate resins described in JP2016-222891A, resins described in JP2020-122052A, resins described in JP2020-111656A, resins described in JP2020-139021A, and resins including a constitutional unit having a ring structure in the main chain and a constitutional unit having a biphenyl group in the side chain, which are described in JP2017-138503A, can also be used. In addition, as the resin, a resin having a fluorene skeleton can also be preferably used. With regard to the resin having a fluorene skeleton, reference can be made to the description in US2017/0102610A, the content of which is incorporated herein by reference. In addition, as the resin, resins described in paragraphs 0199 to 0233 of JP2020-186373A, alkali-soluble resins described in JP2020-186325A, and resins represented by Formula 1, described in KR10-2020-0078339A, can also be used.

As the resin, it is preferable to use a resin having an acid group. Examples of the acid group include a carboxyl group, a phosphoric acid group, a sulfo group, and a phenolic hydroxy group. Among these acid groups, one kind may be used singly, or two or more kinds may be used in combination. The resin having an acid group can be used, for example, as an alkali-soluble resin. An acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 200 mgKOH/g or less, still more preferably 150 mgKOH/g or less, and most preferably 120 mgKOH/g or less.

As the resin, it is also preferable to contain a resin including a repeating unit derived from a compound represented by Formula (ED1) and/or a compound represented by Formula (ED2) (hereinafter, these compounds will also be referred to as an “ether dimer”).

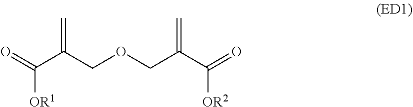

In Formula (ED1), R¹ and R² each independently represent a hydrogen atom or a hydrocarbon group having 1 to 25 carbon atoms, which may have a substituent.

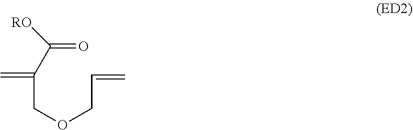

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph 0317 of JP2013-029760A, the contents of which are incorporated herein by reference.

As the resin, it is also preferable to use a resin having a polymerizable group. Examples of the polymerizable group include an ethylenically unsaturated bond-containing group and a cyclic ether group.

In addition, as the resin, it is also preferable to use a resin (hereinafter, also referred to as a resin Ep) having at least one repeating unit (hereinafter, also referred to as a repeating unit Ep) selected from a repeating unit represented by Formula (Ep-1) or a repeating unit represented by Formula (Ep-2). The above-described resin Ep may include only one of the repeating unit represented by Formula (Ep-1) or the repeating unit represented by Formula (Ep-2), or may include both of the repeating unit represented by Formula (Ep-1) and the repeating unit represented by Formula (Ep-2). In a case of including both of the repeating units, a molar ratio of the repeating unit represented by Formula (Ep-1) and the repeating unit represented by Formula (Ep-2) is repeating unit represented by Formula (Ep-1):repeating unit represented by Formula (Ep-2)=preferably 5:95 to 95:5, more preferably 10:90 to 90:10, and still more preferably 20:80 to 80:20.

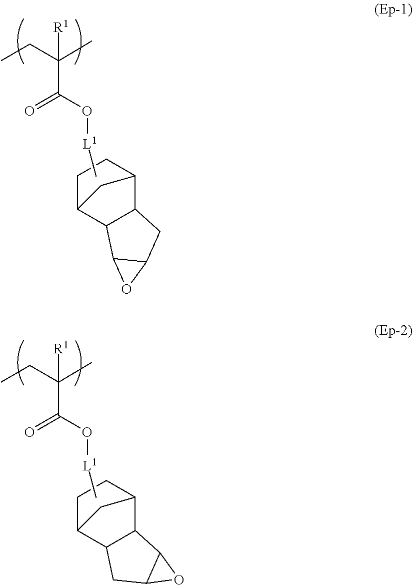

In Formulae (Ep-1) and (Ep-2), ^{L} represents a single bond or a divalent linking group, and R¹ represents a hydrogen atom or a substituent. Examples of the substituent represented by R¹ include an alkyl group and an aryl group, and an alkyl group is preferable. The alkyl group preferably has 1 to 10 carbon atoms, more preferably has 1 to 5 carbon atoms, and still more preferably has 1 to 3 carbon atoms. R¹ is preferably a hydrogen atom or a methyl group. Examples of the divalent linking group represented by L¹ include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more of these groups. The alkylene group may be linear, branched, or cyclic, and is preferably linear or branched. In addition, the alkylene group may have a substituent or may be unsubstituted. Examples of the substituent include a hydroxy group and an alkoxy group.

A content of the above-described repeating unit Ep in the resin Ep is preferably 1 to 100 mol % in all repeating units of the resin Ep. The upper limit is preferably 90 mol % or less and more preferably 80 mol % or less. The lower limit is preferably 2 mol % or more and more preferably 3 mol % or more.

The resin Ep may have a repeating unit other than the above-described repeating unit Ep. Examples of other repeating units include a repeating unit having an acid group and a repeating unit having an ethylenically unsaturated bond-containing group.

Examples of the acid group include a phenolic hydroxy group, a carboxy group, a sulfo group, and a phosphoric acid group, and a phenolic hydroxy group or a carboxy group is preferable and a carboxy group is more preferable.

Examples of the ethylenically unsaturated bond-containing group include a vinyl group, a styrene group, a (meth)allyl group, and a (meth)acryloyl group.

In a case where the resin Ep includes the repeating unit having an acid group, a content of the repeating unit having an acid group in the resin Ep is preferably 5 to 85 mol % in all repeating units of the resin Ep. The upper limit is preferably 60 mol % or less and more preferably 40 mol % or less. The lower limit is preferably 8 mol % or more and more preferably 10 mol % or more.

In a case where the resin Ep includes the repeating unit having an ethylenically unsaturated bond-containing group, a content of the repeating unit having an ethylenically unsaturated bond-containing group in the resin Ep is preferably 1 to 65 mol % with respect to all repeating units of the resin Ep. The upper limit is preferably 45 mol % or less and more preferably 30 mol % or less. The lower limit is preferably 2 mol % or more and more preferably 3 mol % or more.

The resin Ep preferably further includes a repeating unit having an aromatic hydrocarbon ring. The aromatic hydrocarbon ring is preferably a benzene ring or a naphthalene ring and more preferably a benzene ring. The aromatic hydrocarbon ring may have a substituent. Examples of the substituent include an alkyl group. In a case where the resin having a cyclic ether group includes the repeating unit having an aromatic hydrocarbon ring, a content of the repeating unit having an aromatic hydrocarbon ring is preferably 1 to 65 mol % in the total repeating units of the resin having a cyclic ether group. The upper limit is preferably 45 mol % or less and more preferably 30 mol % or less. The lower limit is preferably 2 mol % or more and more preferably 3 mol % or more. Examples of the repeating unit having an aromatic hydrocarbon ring include a repeating unit derived from a monofunctional polymerizable compound having an aromatic hydrocarbon ring, such as vinyltoluene and benzyl (meth)acrylate.

As the resin, it is also preferable to use a resin including a repeating unit derived from a compound represented by Formula (X).

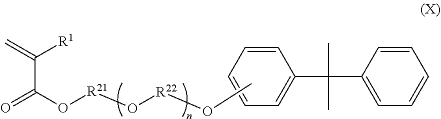

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n is preferably an integer of 0 to 5, more preferably an integer of 0 to 4, and still more preferably an integer of 0 to 3.

Examples of the compound represented by Formula (X) include ethylene oxide- or propylene oxide-modified (meth)acrylate of para-cumylphenol. Examples of a commercially available product thereof include ARONIX M-110 (manufactured by TOAGOSEI CO., LTD.).

As the resin, it is also preferable to use a resin (hereinafter, also referred to as a resin Ac) having an aromatic carboxy group. The resin Ac may include the aromatic carboxy group in the main chain of the repeating unit, or in the side chain of the repeating unit. It is preferable that the aromatic carboxy group is included in the main chain of the repeating unit. In the present specification, the aromatic carboxy group is a group having a structure in which one or more carboxy groups are bonded to an aromatic ring. In the aromatic carboxy group, the number of carboxy groups bonded to an aromatic ring is preferably 1 to 4 and more preferably 1 or 2.

The composition according to the embodiment of the present invention preferably contains a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group is 70 mol % or more in a case where the total amount of the acid group and the basic group is 100 mol %. The acid group included in the acidic dispersant (acidic resin) is preferably a carboxy group. An acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

It is also preferable that the resin used as a dispersant is a graft resin. With regard to details of the graft resin, reference can be made to the description in paragraphs 0025 to 0094 of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraphs 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraphs 0196 to 0209 of JP2013-043962A.

It is also preferable that the resin used as a dispersant is a resin including a repeating unit having an ethylenically unsaturated bond-containing group in the side chain. A content of the repeating unit having an ethylenically unsaturated bond-containing group in the side chain is preferably 10 mol % or more, more preferably 10 to 80 mol %, and still more preferably 20 to 70 mol % with respect to the total repeating units of the resin.

In addition, as the dispersant, a resin described in JP2018-087939A, block copolymers (EB-1) to (EB-9) described in paragraphs 0219 to 0221 of JP6432077B, polyethyleneimine having a polyester side chain, described in WO2016/104803A, a block copolymer described in WO2019/125940A, a block polymer having an acrylamide structural unit, described in JP2020-066687A, a block polymer having an acrylamide structural unit, described in JP2020-066688A, a dispersant described in WO2016/104803A, or the like can also be used.

A commercially available product is also available as the dispersant, and specific examples thereof include DISPERBYK series (for example, DISPERBYK-111, 161, 2001, and the like) manufactured by BYK-Chemie Japan K.K., Solsperse series (for example, Solsperse 20000, 76500, and the like) manufactured by Lubrizol Corporation, and AJISPER series manufactured by Ajinomoto Fine-Techno Co., Inc. In addition, products described in paragraph 0129 of JP2012-137564A and products described in paragraph 0235 of JP2017-194662A can also be used as the dispersant.

A content of the curable compound in the total solid content of the composition is preferably 1% to 70% by mass. The lower limit is preferably 2% by mass or more, more preferably 3% by mass or more, and still more preferably 5% by mass or more. The upper limit is preferably 65% by mass or less and more preferably 60% by mass or less. The curable compound may be used alone or in a combination of two or more kinds thereof. In a case where two or more kinds thereof are used, the total amount thereof is preferably within the above-described range.

In a case where the composition according to the embodiment of the present invention contains a polymerizable compound as the curable compound, a content of the polymerizable compound in the total solid content of the composition is preferably 1% to 70% by mass. The lower limit is preferably 2% by mass or more, more preferably 3% by mass or more, and still more preferably 5% by mass or more. The upper limit is preferably 65% by mass or less and more preferably 60% by mass or less. The polymerizable compound may be used alone or in a combination of two or more kinds thereof. In a case where two or more kinds thereof are used, the total amount thereof is preferably within the above-described range.

In a case where the composition according to the embodiment of the present invention contains a polymerizable monomer as the curable compound, a content of the polymerizable monomer in the total solid content of the composition is preferably 1% to 50% by mass. The lower limit is preferably 2% by mass or more, more preferably 3% by mass or more, and still more preferably 5% by mass or more. The upper limit is preferably 35% by mass or less, more preferably 30% by mass or less, and still more preferably 20% by mass or less. The polymerizable monomer may be used alone or in combination of two or more kinds thereof. In a case where two or more kinds thereof are used, the total amount thereof is preferably within the above-described range.

In a case where the composition according to the embodiment of the present invention contains a resin as the curable compound, a content of the resin in the total solid content of the composition is preferably 1% to 70% by mass. The lower limit is preferably 2% by mass or more, more preferably 3% by mass or more, and still more preferably 5% by mass or more. The upper limit is preferably 65% by mass or less and more preferably 60% by mass or less.

In addition, the content of the resin having an acid group is preferably 1% to 70% by mass in the total solid content of the composition. The lower limit is preferably 2% by mass or more, more preferably 3% by mass or more, and still more preferably 5% by mass or more. The upper limit is preferably 65% by mass or less and more preferably 60% by mass or less.

In addition, the content of the alkali-soluble resin is preferably 1% to 70% by mass in the total solid content of the composition. The lower limit is preferably 2% by mass or more, more preferably 3% by mass or more, and still more preferably 5% by mass or more. The upper limit is preferably 65% by mass or less and more preferably 60% by mass or less.

In a case where the composition according to the embodiment of the present invention contains a resin as a dispersant, a content of the resin as a dispersant in the total solid content of the composition is preferably 0.1% to 30% by mass. The upper limit is more preferably 25% by mass or less and still more preferably 20% by mass or less. The lower limit is preferably 0.5% by mass or more and more preferably 1% by mass or more. In addition, the content of the resin as a dispersant is preferably 1 to 100 parts by mass with respect to 100 parts by mass of the pigment. The upper limit is preferably 80 parts by mass or less, more preferably 70 parts by mass or less, and still more preferably 60 parts by mass or less. The lower limit is preferably 5 parts by mass or more, more preferably 10 parts by mass or more, and still more preferably 20 parts by mass or more.

The resin may be used alone or in combination of two or more kinds thereof. In a case where two or more kinds thereof are used, the total amount thereof is preferably within the above-described range.

### <<Solvent>>

The composition according to the embodiment of the present invention contains a solvent. Examples of the solvent include water and an organic solvent. Basically, the type of the solvent is not particularly limited as long as it satisfies solubility of the respective components or application properties of the composition. Examples of the organic solvent include an aliphatic hydrocarbon-based solvent, a halogenated hydrocarbon-based solvent, an alcohol-based solvent, an ether-based solvent, an ester-based solvent, a ketone-based solvent, a nitrile-based solvent, an amide-based solvent, a sulfoxide-based solvent, and an aromatic solvent. The details of the organic solvent can be found in paragraph 0223 of WO2015/166779A, the content of which is incorporated herein by reference. In addition, an ester-based solvent in which a cyclic alkyl group is substituted or a ketone-based solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, 2-pentanone, 3-pentanone, 4-heptanone, cyclohexanone, 2-methylcyclohexanone, 3-methylcyclohexanone, 4-methylcyclohexanone, cycloheptanone, cyclooctanone, cyclohexyl acetate, cyclopentanone, ethylcarbitol acetate, butylcarbitol acetate, propylene glycol monomethyl ether, propylene glycol monomethyl ether acetate, 3-methoxy-N,N-dimethylpropanamide, 3-butoxy-N,N-dimethylpropanamide, propylene glycol diacetate, 3-methoxybutanol, methyl ethyl ketone, γ-butyrolactone, sulfolane, anisole, 1,4-diacetoxybutane, diethylene glycol monoethyl ether acetate, butane diacetate-1,3-diyl, dipropylene glycol methyl ether acetate, diacetone alcohol (also known as diacetone alcohol or 4-hydroxy-4-methyl-2-pentanone), 2-methoxypropyl acetate, 2-methoxy-1-propanol, and isopropyl alcohol. In this case, the content of aromatic hydrocarbons (such as benzene, toluene, xylene, and ethylbenzene) as the organic solvent may be low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass ppb (parts per billion) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 m or less, more preferably 5 m or less, and still more preferably 3 m or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially contain peroxides.

The content of the solvent in the composition is preferably 10% to 95% by mass, more preferably 20% to 90% by mass, and still more preferably 30% to 90% by mass. The solvent may be used alone or in combination of two or more kinds thereof. In a case where two or more kinds thereof are used, the total amount thereof is preferably within the above-described range.

### <<Coloring Material>>

The composition according to the embodiment of the present invention preferably contains a coloring material. Such a composition can be preferably used as a composition for forming an optical filter (more specifically, for forming a pixel of an optical filter) used in an optical sensor or an image display device.

Examples of the coloring material include a black coloring material, a chromatic coloring material, and a near-infrared absorbing coloring material. In the present specification, the white coloring material includes not only a pure white coloring material but also includes a bright gray (for example, grayish-white, light gray, and the like) coloring material close to white.

It is preferable that the coloring material includes at least one selected from the group consisting of a chromatic coloring material, a black coloring material, and a near-infrared absorbing coloring material, it is more preferable to include at least one selected from the group consisting of a chromatic coloring material and a black coloring material, and it is still more preferable to include a chromatic coloring material.

In addition, the coloring material preferably includes two or more kinds of chromatic coloring materials and a near-infrared absorbing coloring material. In addition, a combination of two or more kinds of chromatic coloring materials may form black. In addition, the coloring material also preferably includes a black coloring material and a near-infrared absorbing coloring material. According to these aspects, the composition according to the embodiment of the present invention can be preferably used as a composition for forming a near-infrared transmitting filter. For a combination of coloring materials which form black with the combination of two or more kinds of chromatic coloring materials, JP2013-077009A, JP2014-130338A, WO2015/166779A, and the like can be referred to.

The coloring material may be a pigment or a dye, but a pigment is preferable. An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In the present specification, the primary particle diameter of the pigment can be determined from a captured image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present specification is an arithmetic average of the primary particle diameters with respect to 400 primary particles of the pigment. In addition, the primary particle of the pigment refers to a particle which is independent without aggregation.

### (Chromatic Coloring Material)

Examples of the chromatic coloring material include a coloring material having a maximal absorption wavelength in a wavelength range of 400 to 700 nm. Examples thereof include a green coloring material, a red coloring material, a yellow coloring material, a violet coloring material, a blue coloring material, and an orange coloring material.

Examples of the green coloring material include a phthalocyanine compound and a squarylium compound, and a phthalocyanine compound is preferable. In addition, the green coloring material is preferably a pigment. Specific examples of the green coloring material include green pigments such as C. I. Pigment Green 7, 10, 36, 37, 58, 59, 62, 63, 64, 65, and 66. In addition, as the green coloring material, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include the compounds described in WO2015/118720A. In addition, as the green coloring material, compounds described in CN2010-6909027A, phthalocyanine compounds described in WO2012/102395A, which have phosphoric acid ester as a ligand, phthalocyanine compounds described in JP2019-008014A, phthalocyanine compounds described in JP2018-180023A, compounds described in JP2019-038958A, aluminum phthalocyanine compounds described in JP2020-070426A, core-shell type coloring agents described in JP2020-076995A, diarylmethane compounds described in JP2020-504758B, and the like can be used.

The green coloring material is preferably C. I. Pigment Green 7, 36, 58, 59, 62, or 63, and more preferably C. I. Pigment Green 7, 36, 58, or 59.

Examples of the red coloring material include a diketopyrrolopyrrole compound, an anthraquinone compound, an azo compound, a naphthol compound, an azomethine compound, a xanthene compound, a quinacridone compound, a perylene compound, and a thioindigo compound; and a diketopyrrolopyrrole compound, an anthraquinone compound, or an azo compound is preferable, and a diketopyrrolopyrrole compound is more preferable. In addition, the red coloring material is preferably a pigment. Specific examples of the red coloring material include red pigments such as Color Index (C. I.) Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294, 295, 296, and 297. In addition, as the red coloring material, diketopyrrolopyrrole compounds described in JP2017-201384A, in which the structure has at least one substituted bromine atom, diketopyrrolopyrrole compounds described in paragraphs 0016 to 0022 of JP6248838B, diketopyrrolopyrrole compounds described in WO2012/102399A, diketopyrrolopyrrole compounds described in WO2012/117965A, brominated diketopyrrolopyrrole compounds described in JP2020-085947A, naphtholazo compounds described in JP2012-229344A, red coloring materials described in JP6516119B, red coloring materials described in JP6525101B, brominated diketopyrrolopyrrole compounds described in paragraph 0229 of JP2020-090632A, anthraquinone compounds described in KR10-2019-0140741A, anthraquinone compounds described in KR10-2019-0140744A, perylene compounds described in JP2020-079396A, perylene compounds described in JP2020-083982A, xanthene compounds described in JP2018-035345A, diketopyrrolopyrrole compounds described in paragraphs 0025 to 0041 of JP2020-066702A, and the like can also be used. In addition, as the red coloring material, a compound having a structure that an aromatic ring group in which a group bonded with an oxygen atom, a sulfur atom, or a nitrogen atom is introduced to an aromatic ring is bonded to a diketopyrrolopyrrole skeleton can be used. As the red coloring material, Lumogen F Orange 240 (manufactured by BASF SE, red pigment, perylene pigment) can also be used.

As the red coloring material, C. I. Pigment Red 122, 177, 179, 254, 255, 264, 269, 272, or 291 is preferable, and C. I. Pigment Red 254, 264, or 272 is more preferable.

Examples of the yellow coloring material include an azo compound, an azomethine compound, an isoindoline compound, a pteridin compound, a quinophthalone compound, and a perylene compound. As the yellow coloring material, a pigment is preferable, an azo pigment, an azomethine pigment, an isoindoline pigment, a pteridin pigment, a quinophthalone pigment, or a perylene pigment is more preferable, and an azo pigment or an azomethine pigment is still more preferable. Specific examples of the yellow coloring material include yellow pigments such as C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232, 233, 234, 235, and 236.

In addition, as the yellow coloring material, an azobarbiturate nickel complex having the following structure can also be used.

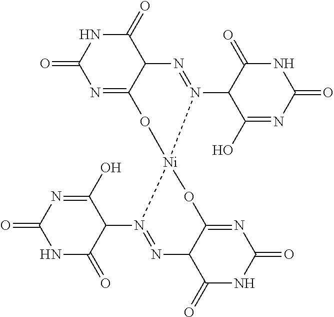

In addition, as the yellow coloring material, compounds described in JP2017-201003A, compounds described in JP2017-197719A, compounds described in paragraphs 0011 to 0062 and 0137 to 0276 of JP2017-171912A, compounds described in paragraphs 0010 to 0062 and 0138 to 0295 of JP2017-171913A, compounds described in paragraphs 0011 to 0062 and 0139 to 0190 of JP2017-171914A, compounds described in paragraphs 0010 to 0065 and 0142 to 0222 of JP2017-171915A, quinophthalone compounds described in paragraphs 0011 to 0034 of JP2013-054339A, quinophthalone compounds described in paragraphs 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, quinophthalone compounds described in JP6607427B, compounds described in KR10-2014-0034963A, compounds described in JP2017-095706A, compounds described in TW2019-20495A, compounds described in JP6607427B, compounds described in JP2020-033525A, compounds described in JP2020-033524A, compounds described in JP2020-033523A, compounds described in JP2020-033522A, compounds described in JP2020-033521A, compounds described in WO2020/045200A, compounds described in WO2020/045199A, compounds described in WO2020/045197A, azo compounds described in JP2020-093994A, perylene compounds described in WO2020/105346A, quinophthalone compounds described in JP2020-517791A, a compound represented by Formula (QP1), and a compound represented by represented by Formula (QP2) can also be used. In addition, from the viewpoint of improving a color value, a multimerized compound of these compounds is also preferably used.

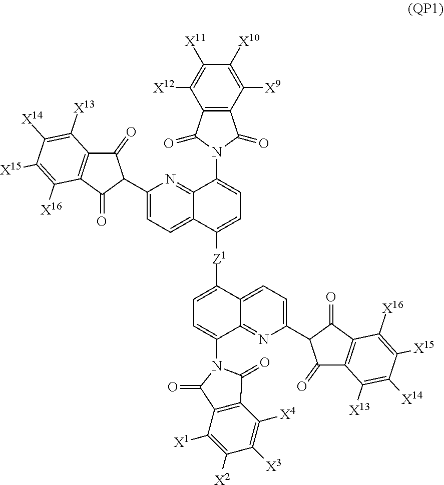

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph 0016 of JP6443711B.

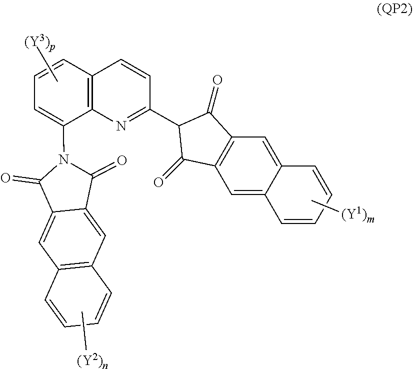

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraphs 0047 and 0048 of JP6432077B.

The yellow coloring material is preferably C. I. Pigment Yellow 117, 129, 138, 139, 150, or 185.

Examples of the orange coloring material include orange pigments such as C. I. Pigment Orange 2, 5, 13, 16, 17:1, 31, 34, 36, 38, 43, 46, 48, 49, 51, 52, 55, 59, 60, 61, 62, 64, 71, and 73.

Examples of the violet coloring material include violet pigments such as C. I. Pigment Violet 1, 19, 23, 27, 32, 37, 42, 60, and 61.

Examples of the blue coloring material include C. I. Pigment Blue 1, 2, 15, 15:1, 15:2, 15:3, 15:4, 15:6, 16, 22, 29, 60, 64, 66, 79, 80, 87, and 88. In addition, as the blue coloring material, an aluminum phthalocyanine compound having a phosphorus atom can also be used. Specific examples thereof include the compounds described in paragraphs 0022 to 0030 of JP2012-247591A and paragraph 0047 of JP2011-157478A.

A dye can also be used as the chromatic coloring material. As the dye, a known dye can be used without any particular limitation. Examples thereof include a pyrazoleazo-based dye, an anilinoazo-based dye, a triarylmethane-based dye, an anthraquinone-based dye, an anthrapyridone-based dye, a benzylidene-based dye, an oxonol-based dye, a pyrazolotriazoleazo-based dye, a pyridoneazo-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, and a pyrromethene-based dye.

A coloring agent multimer can also be used as the chromatic coloring material. The coloring agent multimer is preferably a dye which is used after being dissolved in an organic solvent. In addition, the coloring agent multimer may form a particle. In a case where the coloring agent multimer is a particle, the coloring agent multimer is usually used in a state of being dispersed in a solvent. The coloring agent multimer in the particle state can be obtained by, for example, emulsion polymerization, and specific examples thereof include the compounds and production methods described in JP2015-214682A. The coloring agent multimer has two or more coloring agent structures in one molecule, and preferably has three or more coloring agent structures in one molecule. The upper limit is particularly not limited, but may be 100 or less. A plurality of coloring agent structures included in one molecule may be the same coloring agent structure or different coloring agent structures. A weight-average molecular weight (Mw) of the coloring agent multimer is preferably 2,000 to 50,000. The lower limit is more preferably 3,000 or more and still more preferably 6,000 or more. The upper limit is more preferably 30,000 or less and still more preferably 20,000 or less. As the coloring agent multimer, compounds described in JP2011-213925A, JP2013-041097A, JP2015-028144A, JP2015-030742A, WO2016/031442A, or the like can also be used.

As the chromatic coloring material, diarylmethane compounds described in JP2020-504758A, triarylmethane dye polymers described in KR10-2020-0028160A, xanthene compounds described in JP2020-117638A, phthalocyanine compounds described in WO2020/174991A, isoindoline compounds or salts thereof described in JP2020-160279A, a compound represented by Formula 1, described in KR10-2020-0069442A, a compound represented by Formula 1, described in KR10-2020-0069730A, a compound represented by Formula 1, described in KR10-2020-0069070A, a compound represented by Formula 1, described in KR10-2020-0069067A, a compound represented by Formula 1, described in KR10-2020-0069062A, halogenated zinc phthalocyanine pigments described in JP6809649B, or isoindoline compounds described in JP2020-180176A can be used. The chromatic coloring material may be rotaxane, the coloring agent skeleton may be used in a cyclic structure of the rotaxane, may be used in a rod-like structure, or may be used in both structures.

The chromatic coloring material may be used in a combination of two or more kinds thereof.

In addition, in a case where the chromatic coloring material is used in a combination of two or more kinds thereof, the combination of two or more kinds of chromatic coloring materials may form black. Examples of such a combination include the following aspects (1) to (7).
(1) aspect in which a red coloring material and a blue coloring material are contained.
(2) aspect in which a red coloring material, a blue coloring material, and a yellow coloring material are contained.
(3) aspect in which a red coloring material, a blue coloring material, a yellow coloring material, and a violet coloring material are contained.
(4) aspect in which a red coloring material, a blue coloring material, a yellow coloring material, a violet coloring material, and a green coloring material are contained.
(5) aspect in which a red coloring material, a blue coloring material, a yellow coloring material, and a green coloring material are contained.
(6) aspect in which a red coloring material, a blue coloring material, and a green coloring material are contained.
(7) aspect in which a yellow coloring material and a violet coloring material are contained.

### (White Coloring Material)

Examples of the white coloring material include inorganic pigments (white pigments) such as titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, and zinc sulfide. The white pigment is preferably particles having a titanium atom, more preferably titanium oxide. In addition, the white pigment is preferably a particle having a refractive index of 2.10 or more with respect to light having a wavelength of 589 nm. The above-described refractive index is preferably 2.10 to 3.00 and more preferably 2.50 to 2.75.

In addition, as the white pigment, the titanium oxide described in “Titanium Oxide-Physical Properties and Applied Technology, written by Manabu Kiyono, pages 13 to 45, published on Jun. 25, 1991, published by Gihodo Shuppan Co., Ltd.” can also be used.

The white pigment is not limited to a compound formed of a single inorganic substance, and may be particles combined with other materials. For example, it is preferable to use a particle having a pore or other materials therein, a particle having a number of inorganic particles attached to a core particle, or a core-shell composite particle composed of a core particle formed of polymer particles and a shell layer formed of inorganic fine nanoparticles. With regard to the core-shell composite particle composed of a core particle formed of polymer particles and a shell layer formed of inorganic fine nanoparticles, reference can be made to, for example, the descriptions in paragraphs 0012 to 0042 of JP2015-047520A, the contents of which are incorporated herein by reference.

As the white pigment, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

### (Black Coloring Material)

The black coloring material is not particularly limited, and a known black coloring material can be used. The black coloring material is preferably a pigment (black pigment). In the present specification, the black coloring material means a coloring material which exhibits absorption over the entire wavelength range of 400 to 700 nm. Examples of an inorganic black coloring material include carbon black, titanium black, and graphite, and carbon black or titanium black is preferable and titanium black is more preferable. The titanium black is black particles containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. As the black coloring material, Color Index (C. I.) Pigment Black 1 or 7 can also be used. It is preferable that the titanium black has a small primary particle diameter of the individual particles and has a small average primary particle diameter. Specifically, an average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 1OS, 12S, 13R, 13M, 13M-C, 13R-N, 13M-T (trade name; manufactured by Mitsubishi Materials Corporation) and Tilack D (trade name; manufactured by Akokasei Co., Ltd.).

Examples of an organic black coloring material include a bisbenzofuranone compound, an azomethine compound, a perylene compound, and an azo compound. Among these, a bisbenzofuranone compound or a perylene compound is preferable. Examples of the bisbenzofuranone compound include compounds described in JP2010-534726A, JP2012-515233A, JP2012-515234A, WO2014/208348A, JP2015-525260A, and the like, and the bisbenzofuranone compound is available, for example, as “Irgaphor Black” manufactured by BASF SE. Examples of the perylene compound include C. I. Pigment Black 31 and 32. Examples of the azomethine compound include compounds described in JP1989-170601A (JP-HO1-170601A) and JP1990-034664A (JP-H02-034664A). For example, “CHROMOFINE BLACK A1103” (manufactured by Dainichiseika Color & Chemicals Mfg. Co., Ltd.) is available. In addition, as the organic black coloring material, perylene black (Lumogen Black FK4280 and the like) described in paragraphs 0016 to 0020 of JP2017-226821A may be used.

### (Near-Infrared Absorbing Coloring Material)

The near-infrared absorbing coloring material is preferably a compound having a maximal absorption wavelength in a wavelength range of more than 700 nm and 1400 nm or less. The maximal absorption wavelength of the near-infrared absorbing coloring material is preferably 1200 nm or less, more preferably 1000 nm or less, and still more preferably 950 nm or less. In the near-infrared absorbing coloring material, A550/Amax, which is a ratio of an absorbance A550 at a wavelength of 550 nm to an absorbance Amax at the maximal absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. The near-infrared absorbing coloring material may be a pigment or a dye, but a pigment is preferable and an organic pigment is more preferable.

The near-infrared absorbing coloring material is not particularly limited, and examples thereof include a pyrrolopyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, and a dithiolene metal complex. Examples of the pyrrolopyrrole compound include compounds described in paragraphs 0016 to 0058 of JP2009-263614A, compounds described in paragraphs 0037 to 0052 of JP2011-068731A, and compounds described in paragraphs 0010 to 0033 of WO2015/166873A. Examples of the squarylium compound include compounds described in paragraphs 0044 to 0049 of JP2011-208101A, compounds described in paragraphs 0060 and 0061 of JP6065169B, compounds described in paragraph 0040 of WO2016/181987A, compounds described in JP2015-176046A, compounds described in paragraph 0072 of WO2016/190162A, compounds described in paragraphs 0196 to 0228 of JP2016-074649A, compounds described in paragraph 0124 of JP2017-067963A, compounds described in WO2017/135359A, compounds described in JP2017-114956A, compounds described in JP6197940B, and compounds described in WO2016/120166A. Examples of the cyanine compound include compounds described in paragraphs 0044 and 0045 of JP2009-108267A, compounds described in paragraphs 0026 to 0030 of JP2002-194040A, compounds described in JP2015-172004A, compounds described in JP2015-172102A, compounds described in JP2008-088426A, compounds described in paragraph 0090 of WO2016/190162A, and compounds described in JP2017-031394A. Examples of the croconium compound include compounds described in JP2017-082029A. Examples of the iminium compound include compounds described in JP2008-528706A, compounds described in JP2012-012399A, compounds described in JP2007-092060A, and compounds described in paragraphs 0048 to 0063 of WO2018/043564A. Examples of the phthalocyanine compound include compounds described in paragraph 0093 of JP2012-077153A, oxytitanium phthalocyanine described in JP2006-343631A, compounds described in paragraphs 0013 to 0029 of JP2013-195480A, vanadium phthalocyanine compounds described in JP6081771B, and compounds described in WO2020/071470A. Examples of the naphthalocyanine compound include compounds described in paragraph 0093 of JP2012-077153A. Examples of the dithiolene metal complex include compounds described in JP5733804B.

In addition, as the near-infrared absorbing coloring material, squarylium compounds described in JP2017-197437A, squarylium compounds described in JP2017-025311A, squarylium compounds described in WO2016/154782A, squarylium compounds described in JP5884953B, squarylium compounds described in JP6036689B, squarylium compounds described in JP5810604B, squarylium compounds described in paragraphs 0090 to 0107 of WO2017/213047A, pyrrole ring-containing compounds described in paragraphs 0019 to 0075 of JP2018-054760A, pyrrole ring-containing compounds described in paragraphs 0078 to 0082 of JP2018-040955A, pyrrole ring-containing compounds described in paragraphs 0043 to 0069 of JP2018-002773A, squarylium compounds having an aromatic ring at the α-amide position described in paragraphs 0024 to 0086 of JP2018-041047A, amide-linked squarylium compounds described in JP2017-179131A, compounds having a pyrrole bis-type squarylium skeleton or a croconium skeleton described in JP2017-141215A, dihydrocarbazole bis-type squarylium compounds described in JP2017-082029, asymmetric compounds described in paragraphs 0027 to 0114 of JP2017-068120A, pyrrole ring-containing compounds (carbazole type) described in JP2017-067963A, phthalocyanine compounds described in JP6251530B, squarylium compounds described in JP2020-075959A, copper complex described in KR10-2019-0135217A, and the like can also be used.

A content of the coloring material in the total solid content of the composition is preferably 20% to 80% by mass. The lower limit is preferably 30% by mass or more, more preferably 40% by mass or more, and still more preferably 50% by mass or more. The upper limit is preferably 75% by mass or less and more preferably 70% by mass or less. The coloring material may be used alone or in combination of two or more kinds thereof. In a case where two or more kinds thereof are used, the total amount thereof is preferably within the above-described range.

### <<Photopolymerization Initiator>>

The composition according to the embodiment of the present invention can contain a photopolymerization initiator. In a case where a polymerizable monomer is used as the curable compound, it is preferable to contain a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole compound, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a hexaarylbiimidazole compound, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, and an acylphosphine compound is more preferable, and an oxime compound is still more preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, photopolymerization initiators described in JP2019-044030A, peroxide initiators described in JP2019-167313A, aminoacetophenone-based initiators described in JP2020-055992A, oxime-based photopolymerization initiators described in JP2013-190459A, polymers described in JP2020-172619A, and the compound represented by Formula 1 described in WO2020/152120A, the contents of which are incorporated herein by reference.

Specific examples of the hexaarylbiimidazole compound include 2,2′,4-tris(2-chlorophenyl)-5-(3,4-dimethoxyphenyl)-4,5-diphenyl-1,1′-biimidazole.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF SE). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF SE). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF SE).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraphs 0025 to 0038 of WO2017/164127A, the compounds described in WO2013/167515A, the compounds described in JP5430746B, and compounds described in JP5647738B. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, 2-ethoxycarbonyloxyimino-1-phenylpropane-1-one, and 1-[4-(phenylthio)phenyl]-3-cyclohexyl-propane-1,2-dione-2-(O-acetyloxime). Examples of a commercially available product thereof include Irgacure OXE01, Irgacure OXE02, Irgacure OXE03, and Irgacure OXE04 (all of which are manufactured by BASF SE), TR-PBG-304 and TR-PBG-327 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product thereof include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include compounds described in JP2014-137466A, compounds described in JP6636081B, and compounds described in KR10-2016-0109444A.

An oxime compound having a skeleton in which at least one benzene ring of a carbazole ring is a naphthalene ring can also be used as the photopolymerization initiator. Specific examples of such an oxime compound include the compounds described in WO2013/083505A.

An oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include a compound described in paragraphs 0031 to 0047 of JP2013-114249A and paragraphs 0008 to 0012 and 0070 to 0079 of JP2014-137466A, a compound described in paragraphs 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

An oxime compound in which a substituent having a hydroxy group is bonded to a carbazole skeleton can also be used as the photopolymerization initiator. Examples of such a photopolymerization initiator include compounds described in WO2019/088055A.

As the photopolymerization initiator, an oxime compound having an aromatic ring group Ar^{OX1} in which an electron withdrawing group is introduced into an aromatic ring (hereinafter, also referred to as an oxime compound OX) is used can also be used. Examples of the electron withdrawing group included in the above-described aromatic ring group Ar^{OX1} include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with excellent light resistance, an acyl group is more preferable, and a benzoyl group is still more preferable. The benzoyl group may have a substituent. As the substituent, a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group is preferable, an alkyl group, an alkoxy group, an aryl group, an aryloxy group, a heterocyclic oxy group, an alkylsulfanyl group, an arylsulfanyl group, or an amino group is more preferable, and an alkoxy group, an alkylsulfanyl group, or an amino group is still more preferable.

The oxime compound OX is preferably at least one selected from a compound represented by Formula (OX1) or a compound represented by Formula (OX2), and more preferably a compound represented by Formula (OX2).

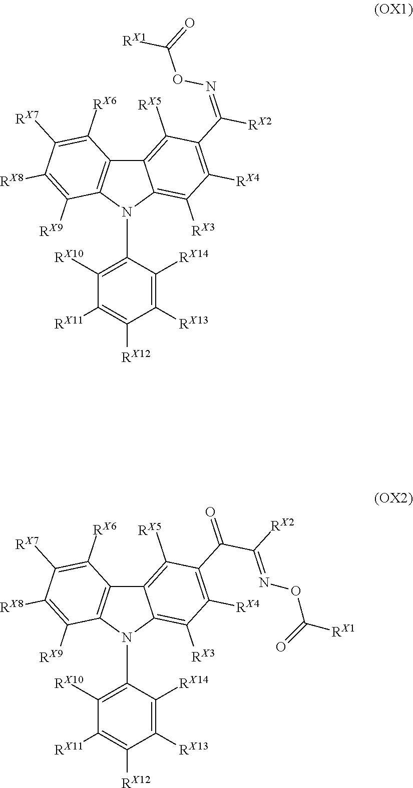

In the formulae, R^{X1} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group.

R^{X2} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group.

R^{X3} to R^{X14} each independently represent a hydrogen atom or a substituent.

However, at least one of R^{X10}, . . . , or R^{X14} is an electron withdrawing group.

Examples of the electron withdrawing group include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with excellent light resistance, an acyl group is more preferable, and a benzoyl group is still more preferable.

In the formulae, it is preferable that R^{X12} is an electron withdrawing group, and R^{X10}, R^{X11}, R^{X13}, and R^{X14} are hydrogen atoms.

Specific examples of the oxime compound OX include compounds described in paragraphs 0083 to 0105 of JP4600600B.

Specific examples of the oxime compound which are preferably used in the present invention are shown below, but the present invention is not limited thereto.

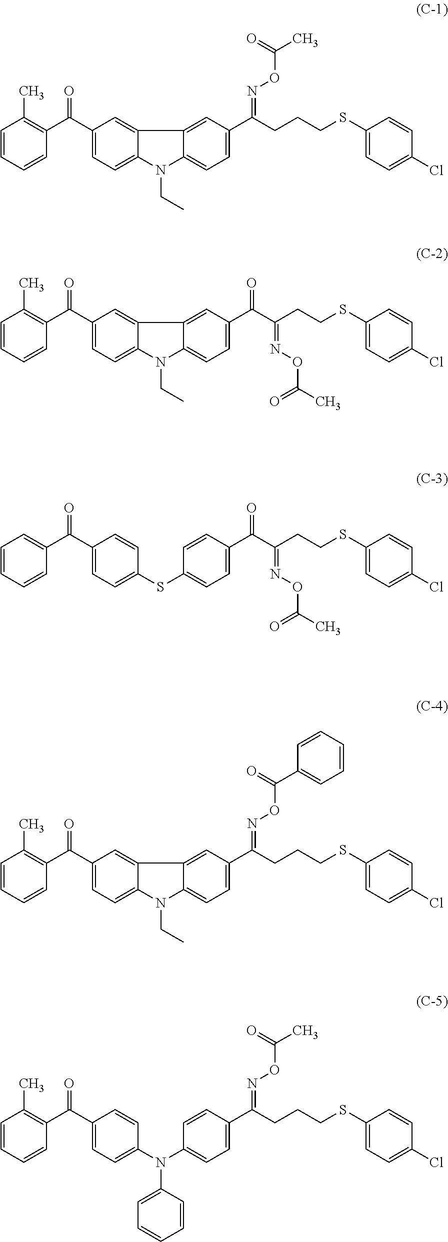 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1]

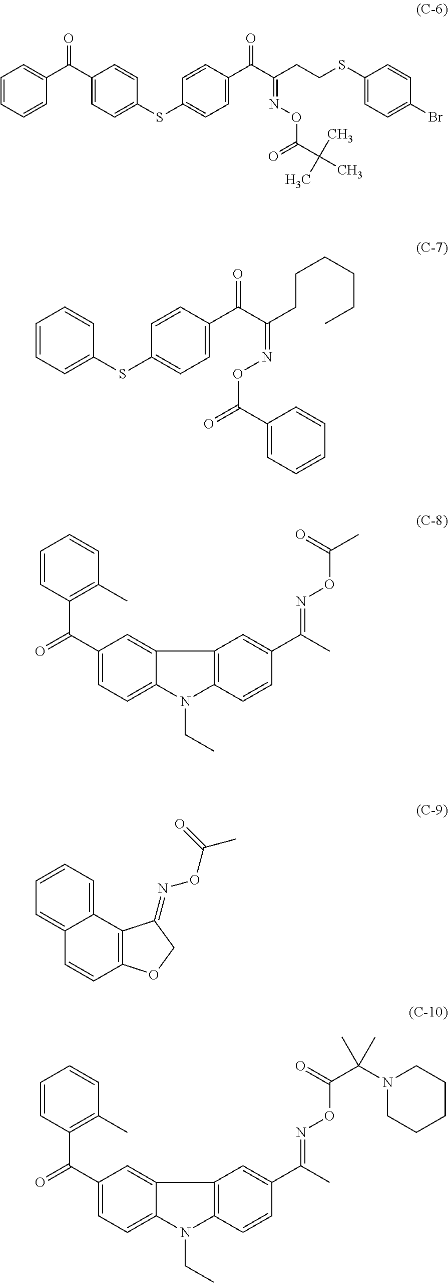 [SMILES: CC(C)(C)C(=O)O/N=C(\CCSc1ccc(Br)cc1)C(=O)c1ccc(Sc2ccc(C(=O)c3ccccc3)cc2)cc1 ; CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21]

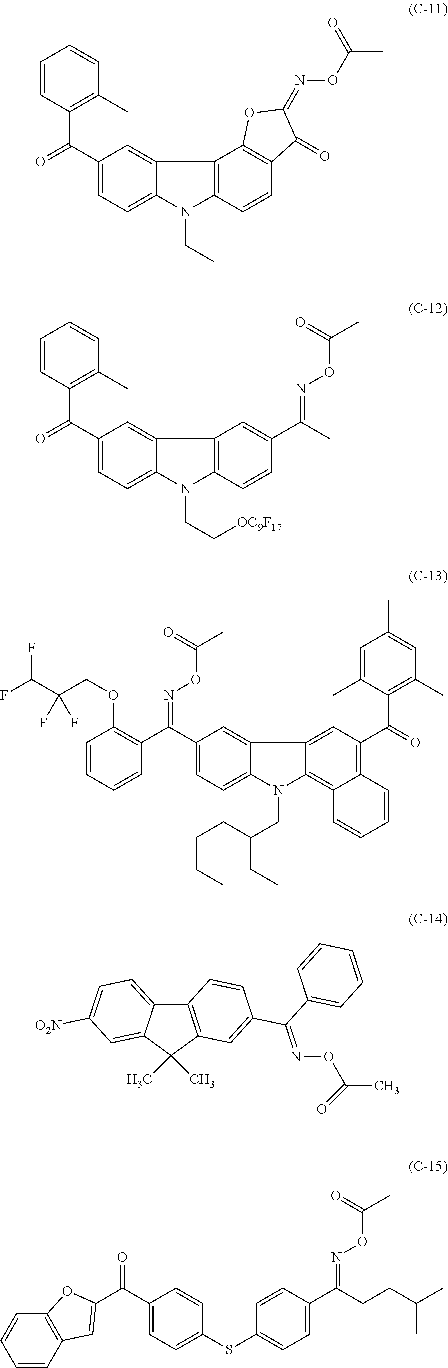

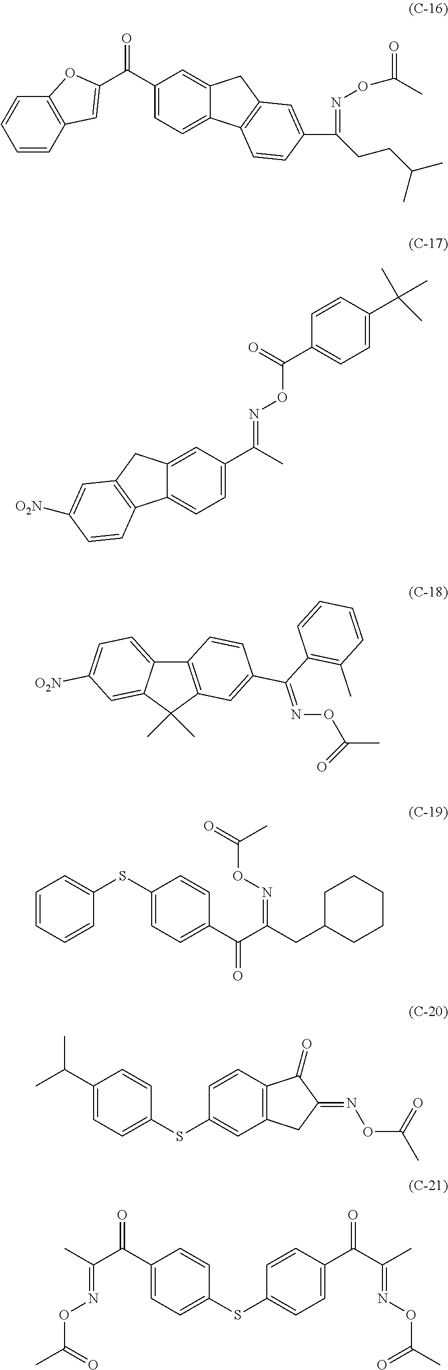

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2,000 to 300,000, and particularly preferably 5,000 to 200,000. The molar absorption coefficient of a compound can be measured using a known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

As the photopolymerization initiator, it is also preferable to use Irgacure OXE01 (manufactured by BASF) and/or Irgacure OXE02 (manufactured by BASF) and Omnirad 2959 (manufactured by IGM Resins B.V.) in combination.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the composition can be improved. Specific examples of the bifunctional or tri- or higher functional photoradical polymerization initiator include dimers of the oxime compounds described in JP2010-527339A, JP2011-524436A, WO2015/004565A, paragraphs 0407 to 0412 of JP2016-532675A, and paragraphs 0039 to 0055 of WO2017/033680A; the compound (E) and compound (G) described in JP2013-522445A; Cmpd 1 to 7 described in WO2016/034963A; the oxime ester-based photoinitiators described in paragraph 0007 of JP2017-523465A; the photoinitiators described in paragraphs 0020 to 0033 of JP2017-167399A; the photopolymerization initiator (A) described in paragraphs 0017 to 0026 of JP2017-151342A; and the oxime ester-based photoinitiators described in JP6469669B.

A content of the photopolymerization initiator in the total solid content of the composition is preferably 0.1% to 20% by mass. The lower limit is preferably 0.5% by mass or more and more preferably 1% by mass or more. The upper limit is preferably 15% by mass or less and more preferably 10% by mass or less. The photopolymerization initiator may be used alone or in a combination of two or more kinds thereof. In a case where two or more kinds thereof are used, the total amount thereof is preferably within the above-described range.

### <<Pigment Derivative>>

The composition according to the embodiment of the present invention may contain a pigment derivative. The pigment derivative is used, for example, as a dispersion aid. Examples of the pigment derivative include a compound having a structure in which an acid group or a basic group is bonded to a coloring agent skeleton.

Examples of the coloring agent skeleton constituting the pigment derivative include a quinoline coloring agent skeleton, a benzoimidazolone coloring agent skeleton, a benzoisoindole coloring agent skeleton, a benzothiazole coloring agent skeleton, an iminium coloring agent skeleton, a squarylium coloring agent skeleton, a croconium coloring agent skeleton, an oxonol coloring agent skeleton, a pyrrolopyrrole coloring agent skeleton, a diketopyrrolopyrrole coloring agent skeleton, an azo coloring agent skeleton, an azomethine coloring agent skeleton, a phthalocyanine coloring agent skeleton, a naphthalocyanine coloring agent skeleton, an anthraquinone coloring agent skeleton, a quinacridone coloring agent skeleton, a dioxazine coloring agent skeleton, a perinone coloring agent skeleton, a perylene coloring agent skeleton, a thioindigo coloring agent skeleton, an isoindrin coloring agent skeleton, a isoindolinone coloring agent skeleton, a quinophthalone coloring agent skeleton, a dithiol coloring agent skeleton, a triarylmethane coloring agent skeleton, and a pyrromethene coloring agent skeleton.

Examples of the acid group include a carboxy group, a sulfo group, a phosphoric acid group, a boronic acid group, a carboxylic acid amide group, a sulfonic acid amide group, an imidic acid group, and salts of these group. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. As the carboxylic acid amide group, a group represented by —NHCOR^{X1} is preferable. As the sulfonic acid amide group, a group represented by —NHSO₂R^{X2} is preferable. As the imidic acid group, a group represented by —SO₂NHSO₂R^{X3}, —CONHSO₂R^{X4}, —CONHCOR^{X5}, or —SO₂NHCOR^{X6} is preferable, and —SO₂NHSO₂R^{X3} is more preferable. R^{X1} to R^{X6} each independently represent an alkyl group or an aryl group. The alkyl group and the aryl group represented by R^{X1} to R^{X6} may have a substituent. As the substituent, a halogen atom is preferable and a fluorine atom is more preferable.

Examples of the basic group included in the pigment derivative include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

As the pigment derivative, a pigment derivative having excellent visible transparency (hereinafter, also referred to as a transparent pigment derivative) can be used. The maximum value (εmax) of a molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of Fmax is, for example, 1 L mol⁻¹ cm¹ or more and may be 10 L·mol⁻¹·cm⁻¹ or more.

Specific examples of the pigment derivative include compounds described in JP1981-118462A (JP-S56-118462A), compounds described in JP1988-264674A (JP-S63-264674A), compounds described in JP1989-217077A (JP-HO1-217077A), compounds described in JP1991-009961A (JP-H03-009961A), compounds described in JP1991-026767A (JP-H03-026767A), compounds described in JP1991-153780A (JP-H03-153780A), compounds described in JP1991-045662A (JP-H03-045662A), compounds described in JP1992-285669A (JP-H04-285669A), compounds described in JP1994-145546A (JP-H06-145546A), compounds described in JP1994-212088A (JP-H06-212088A), compounds described in JP1994-240158A (JP-H06-240158A), compounds described in JP1998-030063A (JP-H10-030063A), compounds described in JP1998-195326A (JP-H10-195326A), compounds described in paragraphs 0086 to 0098 of WO2011/024896A, compounds described in paragraphs 0063 to 0094 of WO2012/102399A, compounds described in paragraph 0082 of WO2017/038252A, compounds described in paragraph 0171 of JP2015-151530A, compounds described in paragraphs 0162 to 0183 of JP2011-252065A, compounds described in JP2003-081972A, compounds described in JP5299151B, compounds described in JP2015-172732A, compounds described in JP2014-199308A, compounds described in JP2014-085562A, compounds described in JP2014-035351A, compounds described in JP2008-081565A, compounds described in JP2019-109512A, compounds described in JP2019-133154A, diketopyrrolopyrrole compounds having a thiol linking group, described in WO2020/002106A, and benzimidazolone compounds or salts thereof, described in JP2018-168244A.

a content of the pigment derivative is preferably 1 to 30 parts by mass and still more preferably 3 to 20 parts by mass with respect to 100 parts by mass of the above-described pigment. In addition, the total content of the pigment derivative and the coloring material in the total solid content of the composition is preferably 35% by mass or more, more preferably 40% by mass or more, still more preferably 45% by mass or more, and particularly preferably 50% by mass or more. The upper limit is preferably 70% by mass or less and more preferably 65% by mass or less. As the pigment derivative, one kind may be used alone, or two or more kinds may be used in combination. In a case where two or more kinds thereof are used, the total amount thereof is preferably within the above-described range.

### <<Polyalkyleneimine>>

The composition according to the embodiment of the present invention can also contain polyalkyleneimine. The polyalkyleneimine is used, for example, as a dispersion aid for the pigment. The dispersion aid is a material for increasing dispersibility of the pigment in the composition. The polyalkyleneimine is a polymer obtained by a ring-opening polymerization of alkyleneimine, and is a polymer having at least a secondary amino group. The polyalkyleneimine may have a primary amino group or a tertiary amino group in addition to the secondary amino group. The polyalkyleneimine is preferably a polymer having a branched structure including each of a primary amino group, a secondary amino group, and a tertiary amino group. The number of carbon atoms in the alkyleneimine is preferably 2 to 6, more preferably 2 to 4, still more preferably 2 or 3, and particularly preferably 2.

A molecular weight of the polyalkyleneimine is preferably 200 or more and more preferably 250 or more. The upper limit thereof is preferably 100,000 or less, more preferably 50,000 or less, still more preferably 10,000 or less, and particularly preferably 2,000 or less. With regard to the value of the molecular weight of the polyalkyleneimine, in a case where the molecular weight can be calculated from a structural formula, the molecular weight of the polyalkyleneimine is a value calculated from the structural formula. On the other hand, in a case where the molecular weight of the specific amine compound cannot be calculated from the structural formula or is difficult to calculate, a value of a number-average molecular weight measured by a boiling point increase method is used. In addition, even in a case where the molecular weight of the polyalkyleneimine cannot be measured by the boiling point increase method or is difficult to be measured, a value of a number-average molecular weight measured by a viscosity method is used. In addition, in a case where the molecular weight of the polyalkyleneimine cannot be measured by the viscosity method or is difficult to be measured by the viscosity method, a value of a number-average molecular weight in terms of polystyrene through measurement by a gel permeation chromatography (GPC) method is used.

An amine value of the polyalkyleneimine is preferably 5 mmol/g or more, more preferably 10 mmol/g or more, and still more preferably 15 mmol/g or more.

Specific examples of the alkyleneimine include ethyleneimine, propyleneimine, 1,2-butyleneimine, and 2,3-butyleneimine, and ethyleneimine or propyleneimine is preferable and ethyleneimine is more preferable. The polyalkyleneimine is particularly preferably polyethyleneimine. In addition, the polyethyleneimine preferably includes the primary amino group in an amount of 10 mol % or more, more preferably includes the primary amino group in an amount of 20 mol % or more, and still more preferably includes the primary amino group in an amount of 30 mol % or more with respect to the total of the primary amino group, the secondary amino group, and the tertiary amino group. Examples of a commercially available product of the polyethyleneimine include EPOMIN SP-003, SP-006, SP-012, SP-018, SP-200, and P-1000 (all of which are manufactured by NIPPON SHOKUBAI CO., LTD.).

A content of the polyalkyleneimine in the total solid content of the composition is preferably 0.1% to 5% by mass. The lower limit is preferably 0.2% by mass or more, more preferably 0.5% by mass or more, and still more preferably 1% by mass or more. The upper limit is preferably 4.5% by mass or less, more preferably 4% by mass or less, and still more preferably 3% by mass or less. In addition, the content of the polyalkyleneimine is preferably 0.5 to 20 parts by mass with respect to 100 parts by mass of the pigment. The lower limit is preferably 0.6 parts by mass or more, more preferably 1 part by mass or more, and still more preferably 2 parts by mass or more. The upper limit is preferably 10 parts by mass or less and more preferably 8 parts by mass or less. The polyalkyleneimine may be used alone or in combination of two or more kinds thereof. In a case where two or more kinds thereof are used, the total amount thereof is preferably within the above-described range.

### <<Curing Accelerator>>

The composition according to the embodiment of the present invention can contain a curing accelerator. Examples of the curing accelerator include a thiol compound, a methylol compound, an amine compound, a phosphonium salt compound, an amidine salt compound, an amide compound, a base generator, an isocyanate compound, an alkoxysilane compound, and an onium salt compound. Specific examples of the curing accelerator include compounds described in paragraphs 0094 to 0097 of WO2018/056189A, compounds described in paragraphs 0246 to 0253 of JP2015-034963A, compounds described in paragraphs 0186 to 0251 of JP2013-041165A, ionic compounds described in JP2014-055114A, compounds described in paragraphs 0071 to 0080 of JP2012-150180A, alkoxysilane compounds having an epoxy group described in JP2011-253054A, compounds described in paragraphs 0085 to 0092 of JP5765059B, and carboxy group-containing epoxy curing agent described in JP2017-036379A. A content of the curing accelerator in the total solid content of the composition is preferably 0.3% to 8.9% by mass and more preferably 0.8% to 6.4% by mass. The curing accelerator may be used alone or in combination of two or more kinds thereof. In a case where two or more kinds thereof are used, the total amount thereof is preferably within the above-described range.

### <<Ultraviolet Absorber>>

The composition according to the embodiment of the present invention can contain an ultraviolet absorber. Examples of the ultraviolet absorber include a conjugated diene compound, an aminodiene compound, a salicylate compound, a benzophenone compound, a benzotriazole compound, an acrylonitrile compound, a hydroxyphenyltriazine compound, an indole compound, and a triazine compound. Specific examples of such a compound include compounds described in paragraphs 0038 to 0052 of JP2009-217221A, paragraphs 0052 to 0072 of JP2012-208374A, paragraphs 0317 to 0334 of JP2013-068814A, and paragraphs 0061 to 0080 of JP2016-162946A, the contents of which are incorporated herein by reference. Examples of a commercially available product of the ultraviolet absorber include UV-503 (manufactured by Daito Chemical Co., Ltd.), Tinuvin series and Uvinul series manufactured by BASF SE, and Sumisorb series manufactured by Sumika Chemtex Co., Ltd. In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraphs 0049 to 0059 of JP6268967B, compounds described in paragraphs 0059 to 0076 of WO2016/181987A, and thioaryl group-substituted benzotriazole type ultraviolet absorbers described in WO2020/137819A can also be used. A content of the ultraviolet absorber in the total solid content of the composition is preferably 0.01% to 10% by mass and more preferably 0.01% to 5% by mass. The ultraviolet absorber may be used alone or in a combination of two or more kinds thereof. In a case where two or more kinds thereof are used, the total amount thereof is preferably within the above-described range.

### <<Polymerization Inhibitor>>

The composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. A content of the polymerization inhibitor in the total solid content of the composition is preferably 0.0001% to 5% by mass. The polymerization inhibitor may be used alone or in combination of two or more kinds thereof. In a case where two or more kinds thereof are used, the total amount thereof is preferably within the above-described range.

### <<Silane Coupling Agent>>

The composition according to the embodiment of the present invention may contain a silane coupling agent. In the present specification, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than a hydrolyzable group include a vinyl group, a (meth)allyl group, a (meth)acryloyl group, a mercapto group, an epoxy group, an oxetanyl group, an amino group, an ureide group, a sulfide group, an isocyanate group, and a phenyl group. Among these, an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), 7-aminopropyl trimethoxysilane (trade name: KBM-903, manufactured by Shin-Etsu Chemical Co., Ltd.), 7-aminopropyl triethoxysilane (trade name: KBE-903, manufactured by Shin-Etsu Chemical Co., Ltd.), 3-methacryloxypropyl methyldimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include compounds described in paragraphs 0018 to 0036 of JP2009-288703A and compounds described in paragraphs 0056 to 0066 of JP2009-242604A, the contents of which are incorporated herein by reference. A content of the silane coupling agent in the total solid content of the composition is preferably 0.01% to 15.0% by mass and more preferably 0.05% to 10.0% by mass. The silane coupling agent may be used alone or in a combination of two or more kinds thereof. In a case where two or more kinds thereof are used, the total amount thereof is preferably within the above-described range.

### <<Antioxidant>>

The composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (all of which are manufactured by ADEKA Corporation). In addition, as the antioxidant, compounds described in paragraphs 0023 to 0048 of JP6268967B, compounds described in WO2017/006600A, compounds described in WO2017/164024A, or compounds described in KR10-2019-0059371A can also be used. A content of the antioxidant in the total solid content of the composition is preferably 0.01% to 20% by mass and more preferably 0.3% to 15% by mass. The antioxidant may be used alone or in combination of two or more kinds thereof. In a case where two or more kinds thereof are used, the total amount thereof is preferably within the above-described range.

### <<Other Components>>

Optionally, the composition according to the embodiment of the present invention may further contain a sensitizer, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph 0183 of JP2012-003225A (corresponding to paragraph 0237 of US2013/0034812A) and paragraphs 0101 to 0104 and 0107 to 0109 of JP2008-250074A, the contents of which are incorporated herein by reference. In addition, optionally, the composition according to the embodiment of the present invention may contain a potential antioxidant. Examples of the potential antioxidant include a compound in which a portion that functions as the antioxidant is protected by a protective group and the protective group is desorbed by heating the compound at 100° C. to 250° C. or by heating the compound at 80° C. to 200° C. in the presence of an acid/a base catalyst. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation).

The composition according to the embodiment of the present invention may contain a light-resistance improver. Examples of the light-resistance improver include the compounds described in paragraphs 0036 and 0037 of JP2017-198787A, the compounds described in paragraphs 0029 to 0034 of JP2017-146350A, the compounds described in paragraphs 0036 and 0037, and 0049 to 0052 of JP2017-129774A, the compounds described in paragraphs 0031 to 0034 and 0058 and 0059 of JP2017-129674A, the compounds described in paragraphs 0036 and 0037, and 0051 to 0054 of JP2017-122803A, the compounds described in paragraphs 0025 to 0039 of WO2017/164127A, the compounds described in paragraphs 0034 to 0047 of JP2017-186546A, the compounds described in paragraphs 0019 to 0041 of JP2015-025116A, the compounds described in paragraphs 0101 to 0125 of JP2012-145604A, the compounds described in paragraphs 0018 to 0021 of JP2012-103475A, the compounds described in paragraphs 0015 to 0018 of JP2011-257591A, the compounds described in paragraphs 0017 to 0021 of JP2011-191483A, the compounds described in paragraphs 0108 to 0116 of JP2011-145668A, and the compounds described in paragraphs 0103 to 0153 of JP2011-253174A.

From the viewpoint of environmental regulation, the use of perfluoroalkyl sulfonic acid and a salt thereof and use of perfluoroalkyl carboxylic acid and a salt thereof may be restricted. In the composition according to the embodiment of the present invention, in a case of reducing a content of the above-described compounds, the content of the perfluoroalkyl sulfonic acid (particularly, perfluoroalkyl sulfonic acid in which a perfluoroalkyl group has 6 to 8 carbon atoms) and a salt thereof and the perfluoroalkyl carboxylic acid (particularly, perfluoroalkyl carboxylic acid in which a perfluoroalkyl group has 6 to 8 carbon atoms) and a salt thereof is preferably in a range of 0.01 ppb to 1,000 ppb, more preferably 0.05 ppb to 500 ppb, and still more preferably 0.1 ppb to 300 ppb with respect to the total solid content of the composition. The composition according to the embodiment of the present invention may be substantially free of the perfluoroalkyl sulfonic acid and a salt thereof and the perfluoroalkyl carboxylic acid and a salt thereof. For example, by using a compound which can substitute for the perfluoroalkyl sulfonic acid and a salt thereof and the perfluoroalkyl carboxylic acid and a salt thereof, a composition which is substantially free of the perfluoroalkyl sulfonic acid and a salt thereof and the perfluoroalkyl carboxylic acid and a salt thereof may be selected. Examples of the compound which can substitute for the regulated compounds include a compound which is excluded from the regulation due to difference in number of carbon atoms of the perfluoroalkyl group. However, the above-described contents do not prevent the use of perfluoroalkyl sulfonic acid and a salt thereof and use of perfluoroalkyl carboxylic acid and a salt thereof. The composition according to the embodiment of the present invention may contain the perfluoroalkyl sulfonic acid and a salt thereof and the perfluoroalkyl carboxylic acid and a salt thereof within the maximum allowable range.

### <Storage Container>

A storage container of the composition is not particularly limited, and a well-known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or compositions. Examples of such a container include the containers described in JP2015-123351A. In addition, for the purpose of preventing metal elution from the container interior wall, improving storage stability of the composition, and suppressing the alteration of components, it is also preferable that the container interior wall is formed of glass, stainless steel, or the like.

### <Manufacturing Method of Composition>

The composition according to the embodiment of the present invention can be produced by mixing the above-described components. During the production of the composition, all the components may be dissolved or dispersed in a solvent at the same time to produce the composition. Optionally, two or more solutions or dispersion liquids in which the respective components are appropriately blended may be prepared, and the solutions or dispersion liquids may be mixed with each other during use (during application) to produce the composition.

In addition, in the production of the coloring composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph 0022 of JP2015-157893A can be suitably used. In addition, in the process of dispersing the pigment, the pigment may be miniaturized in a salt milling step. A material, a device, process conditions, and the like used in the salt milling step can be found in, for example, JP2015-194521A and JP2012-046629A. As the beads used for the dispersion, zirconia, agate, quartz, titania, tungsten carbide, silicon nitride, alumina, stainless steel, glass, or a combination thereof can be used. In addition, an inorganic compound having a Mohs hardness of 2 or more can be used. The above-described may be contained in the composition in an amount of 1 to 10,000 ppm.

During the production of the composition, it is preferable that the composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE) and polyvinylidene fluoride (PVDF); a polyamide-based resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is preferably 0.01 to 7.0 m, more preferably 0.01 to 3.0 m, and still more preferably 0.05 to 0.5 km. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NXEY, DFA4201NAEY, DFA4201J006P, and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components. In addition, the filter can be appropriately selected according to hydrophilicity or hydrophobicity of the composition.

### <Film>

The film according to the embodiment of the present invention is a film formed of the above-described composition according to the embodiment of the present invention. The film according to the embodiment of the present invention can be used for an optical filter such as a color filter, a near-infrared cut filter, and a near-infrared transmitting filter. In addition, the film according to the embodiment of the present invention can also be used as a light shielding film.

A film thickness of the film according to the embodiment of the present invention can be adjusted according to the purpose. For example, the film thickness is preferably 20 m or less, more preferably 10 m or less, and still more preferably 5 m or less. The lower limit of the film thickness is preferably 0.1 m or more, more preferably 0.2 m or more, and still more preferably 0.3 m or more.

In a case where the film according to the embodiment of the present invention is used as a color filter, the film according to the embodiment of the present invention preferably has a hue of green, red, blue, cyan, magenta, or yellow. In addition, the film according to the embodiment of the present invention can be preferably used as a colored pixel of a color filter. Examples of the colored pixel include a red pixel, a blue pixel, a green pixel, a yellow pixel, a cyan pixel, and a magenta pixel.

In a case where the film according to the embodiment of the present invention is used as a near-infrared cut filter, the maximal absorption wavelength of the film according to the embodiment of the present invention is preferably in a wavelength range of 700 to 1800 nm, more preferably in a wavelength range of 700 to 1300 nm, and still more preferably in a wavelength range of 700 to 1100 nm. In addition, in the film, a transmittance of in the entire wavelength range of 400 to 650 nm is preferably 70% or more, more preferably 80% or more, and still more preferably 90% or more. In addition, the transmittance of the film at at least one point in a wavelength range of 700 to 1800 nm is preferably 20% or less. In addition, absorbance Amax/absorbance A550, which is a ratio of an absorbance Amax at a maximal absorption wavelength to an absorbance A550 at a wavelength of 550 nm, is preferably 20 to 500, more preferably 50 to 500, still more preferably 70 to 450, and particularly preferably 100 to 400.

In a case where the film according to the embodiment of the present invention is used as a near-infrared transmitting filter, it is preferable that the film according to the embodiment of the present invention has, for example, any one of the following spectral characteristics (i1) to (i5).
(i1): filter in which the maximum value of a transmittance in a wavelength range of 400 to 640 nm is 20% or less (preferably 15% or less and more preferably 10% or less) and the minimum value of a transmittance in a wavelength range of 800 to 1500 nm is 70% or more (preferably 75% or more and more preferably 80% or more); a film having such spectral characteristics can shield light having a wavelength range of 400 to 640 nm, and can transmit light having a wavelength exceeding 750 nm.
(i2): filter in which the maximum value of a transmittance in a wavelength range of 400 to 750 nm is 20% or less (preferably 15% or less and more preferably 10% or less) and the minimum value of a transmittance in a wavelength range of 900 to 1500 nm is 70% or more (preferably 75% or more and more preferably 80% or more); a film having such spectral characteristics can shield light having a wavelength range of 400 to 750 nm, and can transmit light having a wavelength exceeding 850 nm.
(i3): filter in which the maximum value of a transmittance in a wavelength range of 400 to 830 nm is 20% or less (preferably 15% or less and more preferably 10% or less) and the minimum value of a transmittance in a wavelength range of 1000 to 1500 nm is 70% or more (preferably 75% or more and more preferably 80% or more); a film having such spectral characteristics can shield light having a wavelength range of 400 to 830 nm, and can transmit light having a wavelength exceeding 950 nm.
(i4): filter in which the maximum value of a transmittance in a wavelength range of 400 to 950 nm is 20% or less (preferably 15% or less and more preferably 10% or less) and the minimum value of a transmittance in a wavelength range of 1100 to 1500 nm is 70% or more (preferably 75% or more and more preferably 80% or more); a film having such spectral characteristics can shield light having a wavelength range of 400 to 950 nm, and can transmit light having a wavelength exceeding 1050 nm.
(i5): filter in which the maximum value of a transmittance in a wavelength range of 400 to 1050 nm is 20% or less (preferably 15% or less and more preferably 10% or less) and the minimum value of a transmittance in a wavelength range of 1200 to 1500 nm is 70% or more (preferably 75% or more and more preferably 80% or more); a film having such spectral characteristics can shield light having a wavelength range of 400 to 1050 nm, and can transmit light having a wavelength exceeding 1150 nm.

In a case where the film according to the embodiment of the present invention is used as a light shielding film, an optical density (OD) of the film per film thickness of 1.5 m in a wavelength range of 400 to 1100 nm is preferably 2.5 or more and more preferably 3.0 or more. The upper limit value thereof is not particularly limited, but is preferably 10 or less, in general.

In addition, reflectivity of the above-described film is preferably less than 8%, more preferably less than 6%, and still more preferably less than 4%. The lower limit is preferably 0% or more.

The light shielding film can be used in optical filter and modules used in a personal computer, a tablet PC, a mobile phone, a smartphone, and a digital camera; office automation (OA) instruments such as a printer composite machine and a scanner; industrial instruments such as a surveillance camera, a barcode reader, an automated teller machine (ATM), a high-speed camera, and an instrument having a personal authentication function using facial image authentication or biometric authentication; in-vehicle camera instruments; medical camera instruments such as an endoscope, a capsule endoscope, and a catheter; a biological sensor, a biosensor, a military reconnaissance camera, a camera for a three-dimensional map, a camera for observing weather and sea, a camera for a land resource exploration, space instruments such as an exploration camera for the astronomy of the space and a deep space target; and the like. In addition, the light shielding film can also be used in applications of a micro light emitting diode (LED), a micro organic light emitting diode (OLED), and the like. Examples of the micro LED and micro OLED include examples described in JP2015-500562B and JP2014-533890A. In addition, the light shielding film can also be used for a quantum dot sensor. Examples of the quantum dot sensor include examples described in US2012/37789A and WO2008/131313A.

### <Method for Manufacturing Film>

The film according to the embodiment of the present invention can be formed through a step of applying the composition according to the embodiment of the present invention onto a support. The method for manufacturing the film preferably further includes a step of forming a pattern. Examples of a method for forming the pattern include a photolithography method and a dry etching method, and a photolithography method is preferable.

The pattern formation by the photolithography method preferably includes a step of applying the composition according to the embodiment of the present invention onto a support to form a composition layer, a step of exposing the composition layer in a patterned manner, and a step of removing a non-exposed portion of the composition layer by development to form a pattern. A step of baking the composition layer (pre-baking step) and a step of baking the developed pattern (post-baking step) may be provided, as desired.

In the step of forming the composition layer, a composition layer is formed by applying the composition according to the embodiment of the present invention onto a support. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of substances, or planarize the surface of the substrate.

As a method of applying the composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. The application method using an ink jet method is not particularly limited, and examples thereof include a method (in particular, pp. 115 to 133) described in “Extension of Use of Ink Jet—Infinite Possibilities in Patent-” (published on February, 2005, S.B. Research Co., Ltd.) and methods described in JP2003-262716A, JP2003-185831A, JP2003-261827A, JP2012-126830A, and JP2006-169325A. In addition, with regard to the method of applying the composition, reference can be made to the description in WO2017/030174A and WO2017/018419A, the contents of which are incorporated herein by reference.

The composition layer formed on the support may be dried (pre-baked). In a case of producing a film by a low-temperature process, the pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the composition layer is exposed in a patterned manner (exposure step). For example, the composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1,000 W/m² to 100,000 W/m² (for example, 5,000 W/m², 15,000 W/m², or 35,000 W/m²). Appropriate conditions of each of the oxygen concentration and the exposure illuminance may be combined, and for example, a combination of the oxygen concentration of 10% by volume and the illuminance of 10,000 W/m², a combination of the oxygen concentration of 35% by volume and the illuminance of 20,000 W/m², or the like is available.

Next, the non-exposed portion of the composition layer is removed by development to form a pattern. The non-exposed portion of the composition layer can be removed by development using a developer. As a result, the composition layer of the non-exposed portion in the exposure step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkaline agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-γ-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkaline agent is preferably a compound having a high molecular weight. The concentration of the alkaline agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the composition layer after development while rotating the support on which the composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

The formation of a pattern using a dry etching method can be performed using a method including: a step of applying the composition according to the embodiment of the present invention onto a support to form a composition layer and then curing the entire composition layer to form a cured composition layer; a step of forming a photoresist layer on this cured composition layer; a step of exposing the photoresist layer in a patterned manner and then developing the photoresist layer to form a resist pattern; and a step of dry-etching the cured composition layer with an etching gas using this resist pattern as a mask. It is preferable that pre-baking treatment is further performed in order to form the photoresist layer. In particular, as the forming process of the photoresist layer, it is desirable that a heating treatment after exposure and a heating treatment after development (post-baking treatment) are performed. The details of the pattern formation by the dry etching method can be found in paragraphs 0010 to 0067 of JP2013-064993A, the content of which is incorporated herein by reference.

### <Optical Filter>

The optical filter according to the embodiment of the present invention has the above-described film according to the embodiment of the present invention. Examples of the optical filter include a color filter, a near-infrared transmitting filter, and a near-infrared cut filter, and a color filter is preferable. As the color filter, it is preferable to have the film according to the embodiment of the present invention as a colored pixel of the color filter.

In addition, the optical filter may have a structure in which each pixel is embedded in a space partitioned in, for example, a lattice form by a partition wall.

In addition, the optical filter may have a light shielding film. For example, a color filter, a near-infrared transmitting filter, a near-infrared cut filter, or the like may be formed in the opening portion of the light shielding film formed on the support.

The optical filter according to the embodiment of the present invention can be used in an optical sensor such as a solid-state imaging element, an image display device, or the like.

In the optical filter, a film thickness of the film according to the embodiment of the present invention can be appropriately adjusted depending on the purposes. The film thickness of the pixel included in the optical filter is preferably 5 m or less, more preferably 1 m or less, and still more preferably 0.6 m or less. The lower limit of the film thickness is preferably 0.1 m or more, more preferably 0.2 m or more, and still more preferably 0.3 m or more.

A width of the pixel included in the optical filter is preferably 0.4 to 10.0 m. The lower limit is preferably 0.4 m or more, more preferably 0.5 m or more, and still more preferably 0.6 m or more. The upper limit is preferably 5.0 m or less, more preferably 2.0 m or less, still more preferably 1.0 m or less, and even more preferably 0.8 m or less. In addition, a Young's modulus of the pixel is preferably 0.5 to 20 GPa and more preferably 2.5 to 15 GPa.

Each pixel included in the optical filter preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 109 Ω·cm or more and more preferably 10¹¹ Ω·cm or more. The upper limit is not specified, but is, for example, preferably 10¹⁴ Ω·cm or less. The volume resistivity value of the pixel can be measured using an ultra-high resistance meter 5410 (manufactured by Advantest Corporation).

In addition, in a case where the optical filter includes the light shielding film, a film thickness of the light shielding film is preferably 5 m or less and more preferably 2.5 m or less. The lower limit of the film thickness is preferably 0.1 m or more, more preferably 0.5 m or more, and still more preferably 1 m or more.

In the optical filter, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 m and more preferably 0.1 to 5 m. Examples of a method of forming the protective layer include a method of applying and forming a composition for forming a protective layer, a chemical vapor deposition method, and a method of attaching a molded resin with an adhesive material. Examples of components constituting the protective layer include a (meth)acrylic resin, an ene-thiol resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

The protective layer may contain, as desired, an additive such as organic or inorganic fine particles, an absorber of light (for example, ultraviolet rays, near-infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1% to 70% by mass and still more preferably 1% to 60% by mass with respect to the total mass of the protective layer.

In addition, as the protective layer, protective layers described in paragraphs 0073 to 0092 of JP2017-151176A can also be used.

### <Optical Sensor>

The optical sensor according to the embodiment of the present invention includes the above-described film according to the embodiment of the present invention. Examples of the optical sensor include a solid-state imaging element. The configuration of the solid-state imaging element is not particularly limited as long as the solid-state imaging element is configured so as to function as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light shielding film having openings only over the light receiving section of the photodiodes on the photodiodes and the transfer electrodes; have a device-protective film formed of silicon nitride or the like, which is formed to coat the entire surface of the light shielding film and the light receiving section of the photodiodes, on the light shielding film; and have a color filter on the device-protective film. Furthermore, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice form by a partition wall. In this case, it is preferable that the partition wall has a lower refractive index than each colored pixel. Examples of an imaging device having such a structure include the devices described in JP2012-227478A, JP2014-179577A, and WO2018/043654A. In addition, as described in JP2019-211559A, an ultraviolet absorbing layer may be provided in the structure of the solid-state imaging element to improve light resistance. An imaging device including the solid-state imaging element can also be used as a vehicle camera or a surveillance camera, in addition to a digital camera or electronic apparatus (mobile phones or the like) having an imaging function.

### <Image Display Device>

The image display device according to an embodiment of the present invention includes the above-described film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published on 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published on 1994)”. The liquid crystal display device to which the present invention can be applied is not particularly limited, and can be applied to, for example, liquid crystal display devices employing various systems described in the “Liquid Crystal Display Technology for Next Generation”.

### Examples

Hereinafter, the present invention will be described in more detail with reference to the examples. Materials, used amounts, proportions, treatment details, treatment procedures, and the like shown in the following examples can be appropriately changed within a range not departing from the scope of the present invention. Therefore, the scope of the present invention is not limited to the specific examples described below. Ph in the structural formulae represents a phenyl group.

### <Production of Dispersion Liquid>

A mixed solution obtained by mixing raw materials shown in the following tables was mixed and dispersed for 3 hours using a beads mill (zirconia beads having a diameter of 0.1 mm). Next, using a high-pressure disperser NANO-3000-10 (manufactured by Nippon BEE Chemical Co., Ltd.) equipped with a pressure reducing mechanism, the dispersion liquid was dispersed under a pressure of 2,000 kg/cm² at a flow rate of 500 g/min. The dispersion treatment was repeated a total of 10 times to obtain a dispersion liquid. The numerical values indicating the blending amount shown in the following tables indicate parts by mass. The numerical value of the blending amount of the dispersant is a numerical value expressed in terms of solid contents.

TABLE 1

| | Particles 1 | | Particles 2 | | Particles 3 | | Particles 4 | | Dispersant | | Solvent | |
|---|---|---|---|---|---|---|---|---|---|---|---|---|
| | | Blending | | Blending | | Blending | | Blending | | Blending | | Blending |
| | | amount | | amount | | amount | | amount | | amount | | amount |
| | | (part by | | (part by | | (part by | | (part by | | (part by | | (part by |
| | Type | mass) | Type | mass) | Type | mass) | Type | mass) | Type | mass) | Type | mass) |
| Dispersion | PR254 | 10.6 | PY139 | 4.8 | | | | | D-1 | 4.6 | S-1 | 80 |
| liquid 1 | | | | | | | | | | | | |
| Dispersion | PG36 | 8.5 | PY150 | 6.9 | | | | | D-1 | 4.6 | S-1 | 80 |
| liquid 2 | | | | | | | | | | | | |
| Dispersion | PB15:6 | 12.3 | PV23 | 3.1 | | | | | D-1 | 4.6 | S-1 | 80 |
| liquid 3 | | | | | | | | | | | | |
| Dispersion | PG7 | 15.4 | | | | | | | D-1 | 4.6 | S-1 | 80 |
| liquid 4 | | | | | | | | | | | | |
| Dispersion | PR122 | 15.4 | | | | | | | D-1 | 4.6 | S-1 | 80 |
| liquid 5 | | | | | | | | | | | | |
| Dispersion | PY150 | 15.4 | | | | | | | D-1 | 4.6 | S-1 | 80 |
| liquid 6 | | | | | | | | | | | | |
| Dispersion | IR-1 | 15.4 | | | | | | | D-1 | 4.6 | S-1 | 80 |
| liquid 7 | | | | | | | | | | | | |
| Dispersion | PR254 | 5.7 | PY139 | 2.6 | PB15:6 | 5.5 | PV23 | 1.5 | D-1 | 4.6 | S-1 | 80 |
| liquid 8 | | | | | | | | | | | | |
| Dispersion | TION | 15.4 | | | | | | | D-1 | 4.6 | S-1 | 80 |
| liquid 9 | | | | | | | | | | | | |
| Dispersion | TiO2-1 | 40.2 | | | | | | | D-2 | 12.1 | S-1 | 47.8 |
| liquid 10 | | | | | | | | | | | | |
| Dispersion | TiO2-2 | 15.4 | | | | | | | D-1 | 4.6 | S-1 | 80 |
| liquid 11 | | | | | | | | | | | | |

Among the raw materials listed in the above tables, details of the raw materials shown by abbreviations are as follows.

### [Particles]

PR122: C. I. Pigment Red 122 (red pigment)
PR254: C. I. Pigment Red 254 (red pigment)
PG7: C. I. Pigment Green 7 (green pigment)
PG36: C. I. Pigment Green 36 (green pigment)
PB15:6: C. I. Pigment Blue 15:6 (blue pigment)
PY139: C. I. Pigment Yellow 139 (yellow pigment)
PY150: C. I. Pigment Yellow 150 (yellow pigment)
PV23: C. I. Pigment Violet 23 (violet pigment)
TiON: titanium oxynitride (black pigment)
TiO2-1: MPT-141 (manufactured by Ishihara Sangyo Kasha, Ltd., titanium oxide, white pigment)
TiO2-2: TTO-51 (manufactured by Ishihara Sangyo Kasha, Ltd., titanium oxide, white pigment)
IR-1: compound having the following structure (near-infrared absorbing pigment; a portion of i-C₈H₁₇ and i-C₁₀H₂₁ is a mixture of isomers having different carbon atoms and different branch positions)

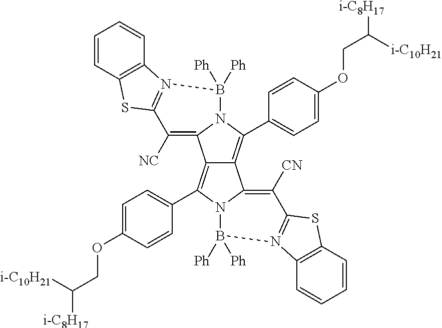

### [Dispersant]

D-1: resin having the following structure (a numerical value added to the main chain represents a molar ratio, and a numerical value added to the side chain represents the number of repeating units; weight-average molecular weight: 24,000, acid value: 47 mgKOH/g)

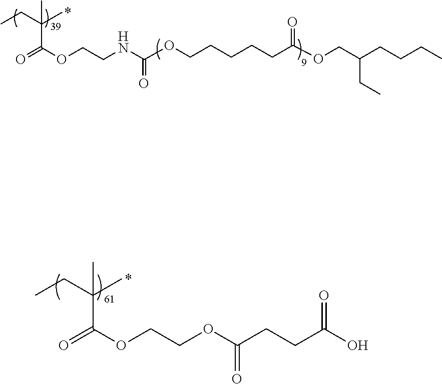

D-2: resin having the following structure (n1/n2=80/20 (mass ratio), n1+n2=30.6, weight-average molecular weight: 12,100, acid value: 156 mgKOH/g)

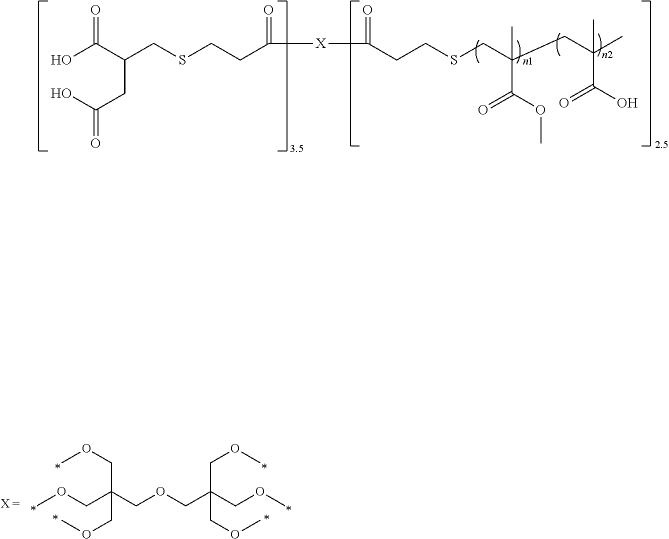

### [Solvent]

S-1: propylene glycol monomethyl ether acetate (PGMEA)

### <Production of Composition>

Raw materials described in the following tables were mixed and filtered using a DFA4201NIEY (0.45 m nylon filter) manufactured by Nihon Pall Corporation to produce a composition. A numerical value of the blending amount of the surfactant in the tables below is a numerical value expressed in terms of solid contents. In addition, the cyclic siloxane compound was adjusted so that the content thereof in the composition was as shown in the tables below. In addition, in the tables below, the value of the proportion of the cyclic siloxane compound to 100 parts by mass of the silicone-based surfactant is shown together in the column of “Proportion of cyclic siloxane compound”.

TABLE 2

| | | | Polymerizable | | | | Photopolymerization | | | |
|---|---|---|---|---|---|---|---|---|---|---|
| | Dispersion liquid | | monomer | | Resin | | initiator | | Surfactant | |
| | | Blending | | Blending | | Blending | | Blending | | Blending |
| | | amount | | amount | | amount | | amount | | amount |
| | | (part by | | (part by | | (part by | | (part by | | (part by |
| | Type | mass) | Type | mass) | Type | mass) | Type | mass) | Type | mass) |
| Example | Dispersion | 65 | M-1 | 3 | B-1 | 7.3 | I-1 | 1.1 | W-1 | 0.0083 |
| 1-1 | liquid 1 | | | | | | | | | |
| Example | Dispersion | 65 | M-1 | 3 | B-1 | 7.3 | I-1 | 1.1 | W-1 | 0.0083 |
| 2-1 | liquid 2 | | | | | | | | | |
| Example | Dispersion | 65 | M-1 | 3 | B-1 | 7.3 | I-1 | 1.1 | W-1 | 0.0083 |
| 3-1 | liquid 3 | | | | | | | | | |
| Example | Dispersion | 65 | M-1 | 3 | B-1 | 7.3 | I-1 | 1.1 | W-1 | 0.0083 |
| 4-1 | liquid 4 | | | | | | | | | |
| Example | Dispersion | 65 | M-1 | 3 | B-1 | 7.3 | I-1 | 1.1 | W-1 | 0.0083 |
| 5-1 | liquid 5 | | | | | | | | | |
| Example | Dispersion | 65 | M-1 | 3 | B-1 | 7.3 | I-1 | 1.1 | W-1 | 0.0083 |
| 6-1 | liquid 6 | | | | | | | | | |
| Example | Dispersion | 65 | M-1 | 3 | B-1 | 7.3 | I-1 | 1.1 | W-1 | 0.0083 |
| 7-1 | liquid 7 | | | | | | | | | |
| Example | Dispersion | 65 | M-1 | 3 | B-1 | 7.3 | I-1 | 1.1 | W-1 | 0.0083 |
| 8-1 | liquid 8 | | | | | | | | | |
| Example | Dispersion | 65 | M-1 | 3 | B-1 | 7.3 | I-1 | 1.1 | W-1 | 0.0083 |
| 9-1 | liquid 9 | | | | | | | | | |
| Example | Dispersion | 52 | M-2 | 9.6 | B-2 | 8.9 | I-2 | 2.7 | W-1 | 0.0083 |
| 10-1 | liquid 10 | | | | | | | | | |
| Example | Dispersion | 65 | M-1 | 3 | B-1 | 7.3 | I-1 | 1.1 | W-1 | 0.0083 |
| 11-1 | liquid 11 | | | | | | | | | |
| Example | Dispersion | 52 | M-1 | 9.6 | B-2 | 8.9 | I-2 | 2.7 | W-1 | 0.0083 |
| 12-1 | liquid 10 | | | | | | | | | |
| Example | Dispersion | 52 | M-1 | 4.8 | B-2 | 8.9 | I-2 | 2.7 | W-1 | 0.0083 |
| 13-1 | liquid 10 | | M-2 | 4.8 | | | | | | |
| Example | Dispersion | 52 | M-2 | 9.6 | B-1 | 8.9 | I-2 | 2.7 | W-1 | 0.0083 |
| 14-1 | liquid 10 | | | | | | | | | |
| Example | Dispersion | 52 | M-2 | 9.6 | B-1 | 4.45 | I-2 | 2.7 | W-1 | 0.0083 |
| 15-1 | liquid 10 | | | | B-2 | 4.45 | | | | |
| Example | Dispersion | 52 | M-2 | 9.6 | B-2 | 8.9 | I-3 | 2.7 | W-1 | 0.0083 |
| 16-1 | liquid 10 | | | | | | | | | |
| Example | Dispersion | 52 | M-2 | 9.6 | B-2 | 8.9 | I-2 | 2.6 | W-1 | 0.0083 |
| 17-1 | liquid 10 | | | | | | I-3 | 0.1 | | |

TABLE 3

| | Additive | | Solvent | | Cyclic siloxane compound | | |
|---|---|---|---|---|---|---|---|
| | | Blending | | Blending | | Blending | |
| | | amount | | amount | | amount | Proportion of cyclic |
| | | (part by | | (part by | | (part by | siloxane compound |
| | Type | mass) | Type | mass) | Type | mass) | (part by mass) |
| Example 1-1 | | | S-1 | 23.6 | Sil-1 | 0.24 | 2.3 |
| | | | | | Sil-2 | 0.83 | |
| | | | | | Sil-3 | 0.83 | |
| Example 2-1 | | | S-1 | 23.6 | Sil-1 | 0.24 | 2.3 |
| | | | | | Sil-2 | 0.83 | |
| | | | | | Sil-3 | 0.83 | |
| Example 3-1 | | | S-1 | 23.6 | Sil-1 | 0.24 | 2.3 |
| | | | | | Sil-2 | 0.83 | |
| | | | | | Sil-3 | 0.83 | |
| Example 4-1 | | | S-1 | 23.6 | Sil-1 | 0.24 | 2.3 |
| | | | | | Sil-2 | 0.83 | |
| | | | | | Sil-3 | 0.83 | |
| Example 5-1 | | | S-1 | 23.6 | Sil-1 | 0.24 | 2.3 |
| | | | | | Sil-2 | 0.83 | |
| | | | | | Sil-3 | 0.83 | |
| Example 6-1 | | | S-1 | 23.6 | Sil-1 | 0.24 | 2.3 |
| | | | | | Sil-2 | 0.83 | |
| | | | | | Sil-3 | 0.83 | |
| Example 7-1 | | | S-1 | 23.6 | Sil-1 | 0.24 | 2.3 |
| | | | | | Sil-2 | 0.83 | |
| | | | | | Sil-3 | 0.83 | |
| Example 8-1 | | | S-1 | 23.6 | Sil-1 | 0.24 | 2.3 |
| | | | | | Sil-2 | 0.83 | |
| | | | | | Sil-3 | 0.83 | |
| Example 9-1 | | | S-1 | 23.6 | Sil-1 | 0.24 | 2.3 |
| | | | | | Sil-2 | 0.83 | |
| | | | | | Sil-3 | 0.83 | |
| Example 10-1 | A-1 | 0.25 | S-1 | 11.8 | Sil-1 | 0.24 | 2.3 |
| | A-2 | 2.5 | S-2 | 11.9 | Sil-2 | 0.83 | |
| | | | | | Sil-3 | 0.83 | |
| Example 11-1 | | | S-1 | 23.6 | Sil-1 | 0.24 | 2.3 |
| | | | | | Sil-2 | 0.83 | |
| | | | | | Sil-3 | 0.83 | |
| Example 12-1 | A-1 | 0.25 | S-1 | 11.8 | Sil-1 | 0.24 | 2.3 |
| | A-2 | 2.5 | S-2 | 11.9 | Sil-2 | 0.83 | |
| | | | | | Sil-3 | 0.83 | |
| Example 13-1 | A-1 | 0.25 | S-1 | 11.8 | Sil-1 | 0.24 | 2.3 |
| | A-2 | 2.5 | S-2 | 11.9 | Sil-2 | 0.83 | |
| | | | | | Sil-3 | 0.83 | |
| Example 14-1 | A-1 | 0.25 | S-1 | 11.8 | Sil-1 | 0.24 | 2.3 |
| | A-2 | 2.5 | S-2 | 11.9 | Sil-2 | 0.83 | |
| | | | | | Sil-3 | 0.83 | |
| Example 15-1 | A-1 | 0.25 | S-1 | 11.8 | Sil-1 | 0.24 | 2.3 |
| | A-2 | 2.5 | S-2 | 11.9 | Sil-2 | 0.83 | |
| | | | | | Sil-3 | 0.83 | |
| Example 16-1 | A-1 | 0.25 | S-1 | 11.8 | Sil-1 | 0.24 | 2.3 |
| | A-2 | 2.5 | S-2 | 11.9 | Sil-2 | 0.83 | |
| | | | | | Sil-3 | 0.83 | |
| Example 17-1 | A-1 | 0.25 | S-1 | 11.8 | Sil-1 | 0.24 | 2.3 |
| | A-2 | 2.5 | S-2 | 11.9 | Sil-2 | 0.83 | |
| | | | | | Sil-3 | 0.83 | |

TABLE 4

| | | | Polymerizable | | | | Photopolymerization | | | |
|---|---|---|---|---|---|---|---|---|---|---|
| | Dispersion liquid | | monomer | | Resin | | initiator | | Surfactant | |
| | | Blending | | Blending | | Blending | | Blending | | Blending |
| | | amount | | amount | | amount | | amount | | amount |
| | | (part by | | (part by | | (part by | | (part by | | (part by |
| | Type | mass) | Type | mass) | Type | mass) | Type | mass) | Type | mass) |
| Example | Dispersion | 65 | M-1 | 3 | B-1 | 7.3 | I-1 | 1.1 | W-2 | 0.0083 |
| 1-2 | liquid 1 | | | | | | | | | |
| Example | Dispersion | 65 | M-1 | 3 | B-1 | 7.3 | I-1 | 1.1 | W-2 | 0.0083 |
| 2-2 | liquid 2 | | | | | | | | | |
| Example | Dispersion | 65 | M- | 3 | B-1 | 7.3 | I-1 | 1.1 | W-2 | 0.0083 |
| 3-2 | liquid 3 | | | | | | | | | |
| Example | Dispersion | 65 | M-1 | 3 | B-1 | 7.3 | I-1 | 1.1 | W-2 | 0.0083 |
| 4-2 | liquid 4 | | | | | | | | | |
| Example | Dispersion | 65 | M- | 3 | B-1 | 7.3 | I-1 | 1.1 | W-2 | 0.0083 |
| 5-2 | liquid 5 | | | | | | | | | |
| Example | Dispersion | 65 | M-1 | 3 | B-1 | 7.3 | I-1 | 1.1 | W-2 | 0.0083 |
| 6-2 | liquid 6 | | | | | | | | | |
| Example | Dispersion | 65 | M-1 | 3 | B-1 | 7.3 | I-1 | 1.1 | W-2 | 0.0083 |
| 7-2 | liquid 7 | | | | | | | | | |
| Example | Dispersion | 65 | M-1 | 3 | B-1 | 7.3 | I-1 | 1.1 | W-2 | 0.0083 |
| 8-2 | liquid 8 | | | | | | | | | |
| Example | Dispersion | 65 | M-1 | 3 | B-1 | 7.3 | I-1 | 1.1 | W-2 | 0.0083 |
| 9-2 | liquid 9 | | | | | | | | | |
| Example | Dispersion | 52 | M-2 | 9.6 | B-2 | 8.9 | I-2 | 2.7 | W-2 | 0.0083 |
| 10-2 | liquid 10 | | | | | | | | | |
| Example | Dispersion | 65 | M-1 | 3 | B-1 | 7.3 | I-1 | 1.1 | W-2 | 0.0083 |
| 11-2 | liquid 11 | | | | | | | | | |
| Example | Dispersion | 52 | M-1 | 9.6 | B-2 | 8.9 | I-2 | 2.7 | W-2 | 0.0083 |
| 12-2 | liquid 10 | | | | | | | | | |
| Example | Dispersion | 52 | M-1 | 4.8 | B-2 | 8.9 | I-2 | 2.7 | W-2 | 0.0083 |
| 13-2 | liquid 10 | | M-2 | 4.8 | | | | | | |
| Example | Dispersion | 52 | M-2 | 9.6 | B-1 | 8.9 | I-2 | 2.7 | W-2 | 0.0083 |
| 14-2 | liquid 10 | | | | | | | | | |
| Example | Dispersion | 52 | M-2 | 9.6 | B-1 | 4.45 | I-2 | 2.7 | W-2 | 0.0083 |
| 15-2 | liquid 10 | | | | B-2 | 4.45 | | | | |
| Example | Dispersion | 52 | M-2 | 9.6 | B-2 | 8.9 | I-3 | 2.7 | W-2 | 0.0083 |
| 16-2 | liquid 10 | | | | | | | | | |
| Example | Dispersion | 52 | M-2 | 9.6 | B-2 | 8.9 | I-2 | 2.6 | W-2 | 0.0083 |
| 17-2 | liquid 10 | | | | | | I-3 | 0.1 | | |

TABLE 5

| | Additive | | Solvent | | Cyclic siloxane compound | | |
|---|---|---|---|---|---|---|---|
| | | Blending | | Blending | | Blending | |
| | | amount | | amount | | amount | Proportion of cyclic |
| | | (part by | | (part by | | (part by | siloxane compound |
| | Type | mass) | Type | mass) | Type | mass) | (part by mass) |
| Example 1-2 | | | S-1 | 23.6 | Sil-1 | 0.8 | 1 |
| Example 2-2 | | | S-1 | 23.6 | Sil-1 | 0.8 | 1 |
| Example 3-2 | | | S-1 | 23.6 | Sil-1 | 0.8 | 1 |
| Example 4-2 | | | S-1 | 23.6 | Sil-1 | 0.8 | 1 |
| Example 5-2 | | | S-1 | 23.6 | Sil-1 | 0.8 | 1 |
| Example 6-2 | | | S-1 | 23.6 | Sil-1 | 0.8 | 1 |
| Example 7-2 | | | S-1 | 23.6 | Sil-1 | 0.8 | 1 |
| Example 8-2 | | | S-1 | 23.6 | Sil-1 | 0.8 | 1 |
| Example 9-2 | | | S-1 | 23.6 | Sil-1 | 0.8 | 1 |
| Example 10-2 | A-1 | 0.25 | S-1 | 11.8 | Sil-1 | 0.8 | 1 |
| | A-2 | 2.5 | S-2 | 11.9 | | | |
| Example 11-2 | | | S-1 | 23.6 | Sil-1 | 0.8 | 1 |
| Example | A-1 | 0.25 | S-1 | 11.8 | Sil-1 | 0.8 | 1 |
| 12-2 | A-2 | 2.5 | S-2 | 11.9 | | | |
| Example | A-1 | 0.25 | S-1 | 11.8 | Sil-1 | 0.8 | 1 |
| 13-2 | A-2 | 2.5 | S-2 | 11.9 | | | |
| Example 14-2 | A-1 | 0.25 | S-1 | 11.8 | Sil-1 | 0.8 | 1 |
| | A-2 | 2.5 | S-2 | 11.9 | | | |
| Example 15-2 | A-1 | 0.25 | S-1 | 11.8 | Sil-1 | 0.8 | 1 |
| | A-2 | 2.5 | S-2 | 11.9 | | | |
| Example | A-1 | 0.25 | S-1 | 11.8 | Sil-1 | 0.8 | 1 |
| 16-2 | A-2 | 2.5 | S-2 | 11.9 | | | |
| Example 17-2 | A-1 | 0.25 | S-1 | 11.8 | Sil-1 | 0.8 | 1 |
| | A-2 | 2.5 | S-2 | 11.9 | | | |

TABLE 6

| | | | Polymerizable | | | | Photopolymerization | | | |
|---|---|---|---|---|---|---|---|---|---|---|
| | Dispersion liquid | | monomer | | Resin | | initiator | | Surfactant | |
| | | Blending | | Blending | | Blending | | Blending | | Blending |
| | | amount | | amount | | amount | | amount | | amount |
| | | (part by | | (part by | | (part by | | (part by | | (part by |
| | Type | mass) | Type | mass) | Type | mass) | Type | mass) | Type | mass) |
| Example | Dispersion | 65 | M-1 | 3 | B-1 | 7.3 | I-1 | 1.1 | W-3 | 0.0083 |
| 1-3 | liquid 1 | | | | | | | | | |
| Example | Dispersion | 65 | M-1 | 3 | B-1 | 7.3 | I-1 | 1.1 | W-3 | 0.0083 |
| 2-3 | liquid 2 | | | | | | | | | |
| Example | Dispersion | 65 | M-1 | 3 | B-1 | 7.3 | I-1 | 1.1 | W-3 | 0.0083 |
| 3-3 | liquid 3 | | | | | | | | | |
| Example | Dispersion | 65 | M-1 | 3 | B-1 | 7.3 | I-1 | 1.1 | W-3 | 0.0083 |
| 4-3 | liquid 4 | | | | | | | | | |
| Example | Dispersion | 65 | M-1 | 3 | B-1 | 7.3 | I-1 | 1.1 | W-3 | 0.0083 |
| 5-3 | liquid 5 | | | | | | | | | |
| Example | Dispersion | 65 | M-1 | 3 | B-1 | 7.3 | I-1 | 1.1 | W-3 | 0.0083 |
| 6-3 | liquid 6 | | | | | | | | | |
| Example | Dispersion | 65 | M-1 | 3 | B-1 | 7.3 | I-1 | 1.1 | W-3 | 0.0083 |
| 7-3 | liquid 7 | | | | | | | | | |
| Example | Dispersion | 65 | M-1 | 3 | B-1 | 7.3 | I-1 | 1.1 | W-3 | 0.0083 |
| 8-3 | liquid 8 | | | | | | | | | |
| Example | Dispersion | 65 | M-1 | 3 | B-1 | 7.3 | I-1 | 1.1 | W-3 | 0.0083 |
| 9-3 | liquid 9 | | | | | | | | | |
| Example | Dispersion | 52 | M-2 | 9.6 | B-2 | 8.9 | I-2 | 2.7 | W-3 | 0.0083 |
| 10-3 | liquid 10 | | | | | | | | | |
| Example | Dispersion | 65 | M-1 | 3 | B-1 | 7.3 | I-1 | 1.1 | W-3 | 0.0083 |
| 11-3 | liquid 11 | | | | | | | | | |
| Example | Dispersion | 52 | M-1 | 9.6 | B-2 | 8.9 | I-2 | 2.7 | W-3 | 0.0083 |
| 12-3 | liquid 10 | | | | | | | | | |
| Example | Dispersion | 52 | M-1 | 4.8 | B-2 | 8.9 | I-2 | 2.7 | W-3 | 0.0083 |
| 13-3 | liquid 10 | | M-2 | 4.8 | | | | | | |
| Example | Dispersion | 52 | M-2 | 9.6 | B-1 | 8.9 | I-2 | 2.7 | W-3 | 0.0083 |
| 14-3 | liquid 10 | | | | | | | | | |
| Example | Dispersion | 52 | M-2 | 9.6 | B-1 | 4.45 | I-2 | 2.7 | W-3 | 0.0083 |
| 15-3 | liquid 10 | | | | B-2 | 4.45 | | | | |
| Example | Dispersion | 52 | M-2 | 9.6 | B-2 | 8.9 | I-3 | 2.7 | W-3 | 0.0083 |
| 16-3 | liquid 10 | | | | | | | | | |
| Example | Dispersion | 52 | M-2 | 9.6 | B-2 | 8.9 | I-2 | 2.6 | W-3 | 0.0083 |
| 17-3 | liquid 10 | | | | | | I-3 | 0.1 | | |

TABLE 7

| | Additive | | Solvent | | Cyclic siloxane compound | | |
|---|---|---|---|---|---|---|---|
| | | Blending | | Blending | | Blending | |
| | | amount | | amount | | amount | Proportion of cyclic |
| | | (part by | | (part by | | (part by | siloxane compound |
| | Type | mass) | Type | mass) | Type | mass) | (part by mass) |
| Example 1-3 | | | S-1 | 23.6 | Sil-1 | 0.8 | 1 |
| Example 2-3 | | | S-1 | 23.6 | Sil-1 | 0.8 | 1 |
| Example 3-3 | | | S-1 | 23.6 | Sil-1 | 0.8 | 1 |
| Example 4-3 | | | S-1 | 23.6 | Sil-1 | 0.8 | 1 |
| Example 5-3 | | | S-1 | 23.6 | Sil-1 | 0.8 | 1 |
| Example 6-3 | | | S-1 | 23.6 | Sil-1 | 0.8 | 1 |
| Example 7-3 | | | S-1 | 23.6 | Sil-1 | 0.8 | 1 |
| Example 8-3 | | | S-1 | 23.6 | Sil-1 | 0.8 | 1 |
| Example 9-3 | | | S-1 | 23.6 | Sil-1 | 0.8 | 1 |
| Example 10-3 | A-1 | 0.25 | S-1 | 11.8 | Sil-1 | 0.8 | 1 |
| | A-2 | 2.5 | S-2 | 11.9 | | | |
| Example 11-3 | | | S-1 | 23.6 | Sil-1 | 0.8 | 1 |
| Example 12-3 | A-1 | 0.25 | S-1 | 11.8 | Sil-1 | 0.8 | 1 |
| | A-2 | 2.5 | S-2 | 11.9 | | | |
| Example 13-3 | A-1 | 0.25 | S-1 | 11.8 | Sil-1 | 0.8 | 1 |
| | A-2 | 2.5 | S-2 | 11.9 | | | |
| Example 14-3 | A-1 | 0.25 | S-1 | 11.8 | Sil-1 | 0.8 | 1 |
| | A-2 | 2.5 | S-2 | 11.9 | | | |
| Example 15-3 | A-1 | 0.25 | S-1 | 11.8 | Sil-1 | 0.8 | 1 |
| | A-2 | 2.5 | S-2 | 11.9 | | | |
| Example 16-3 | A-1 | 0.25 | S-1 | 11.8 | Sil-1 | 0.8 | 1 |
| | A-2 | 2.5 | S-2 | 11.9 | | | |
| Example 17-3 | A-1 | 0.25 | S-1 | 11.8 | Sil-1 | 0.8 | 1 |
| | A-2 | 2.5 | S-2 | 11.9 | | | |

TABLE 8

| | | | Polymerizable | | | | Photopolymerization | | | |
|---|---|---|---|---|---|---|---|---|---|---|
| | Dispersion liquid | | monomer | | Resin | | initiator | | Surfactant | |
| | | Blending | | Blending | | Blending | | Blending | | Blending |
| | | amount | | amount | | amount | | amount | | amount |
| | | (part by | | (part by | | (part by | | (part by | | (part by |
| | Type | mass) | Type | mass) | Type | mass) | Type | mass) | Type | mass) |
| Example | Dispersion | 65 | M-1 | 3 | B-1 | 7.3 | I-1 | 1.1 | W-4 | 0.0083 |
| 1-4 | liquid 1 | | | | | | | | | |
| Example | Dispersion | 65 | M-1 | 3 | B-1 | 7.3 | I-1 | 1.1 | W-4 | 0.0083 |
| 2-4 | liquid 2 | | | | | | | | | |
| Example | Dispersion | 65 | M-1 | 3 | B-1 | 7.3 | I-1 | 1.1 | W-4 | 0.0083 |
| 3-4 | liquid 3 | | | | | | | | | |
| Example | Dispersion | 65 | M-1 | 3 | B-1 | 7.3 | I-1 | 1.1 | W-4 | 0.0083 |
| 4-4 | liquid 4 | | | | | | | | | |
| Example | Dispersion | 65 | M-1 | 3 | B-1 | 7.3 | I-1 | 1.1 | W-4 | 0.0083 |
| 5-4 | liquid 5 | | | | | | | | | |
| Example | Dispersion | 65 | M-1 | 3 | B-1 | 7.3 | I-1 | 1.1 | W-4 | 0.0083 |
| 6-4 | liquid 6 | | | | | | | | | |
| Example | Dispersion | 65 | M-1 | 3 | B-1 | 7.3 | I-1 | 1.1 | W-4 | 0.0083 |
| 7-4 | liquid 7 | | | | | | | | | |
| Example | Dispersion | 65 | M-1 | 3 | B-1 | 7.3 | I-1 | 1.1 | W-4 | 0.0083 |
| 8-4 | liquid 8 | | | | | | | | | |
| Example | Dispersion | 65 | M-1 | 3 | B-1 | 7.3 | I-1 | 1.1 | W-4 | 0.0083 |
| 9-4 | liquid 9 | | | | | | | | | |
| Example | Dispersion | 52 | M-2 | 9.6 | B-2 | 8.9 | I-2 | 2.7 | W-4 | 0.0083 |
| 10-4 | liquid 10 | | | | | | | | | |
| Example | Dispersion | 65 | M-1 | 3 | B-1 | 7.3 | I-1 | 1.1 | W-4 | 0.0083 |
| 11-4 | liquid 11 | | | | | | | | | |
| Example | Dispersion | 52 | M-1 | 9.6 | B-2 | 8.9 | I-2 | 2.7 | W-4 | 0.0083 |
| 12-4 | liquid 10 | | | | | | | | | |
| Example | Dispersion | 52 | M-1 | 4.8 | B-2 | 8.9 | I-2 | 2.7 | W-4 | 0.0083 |
| 13-4 | liquid 10 | | M-2 | 4.8 | | | | | | |
| Example | Dispersion | 52 | M-2 | 9.6 | B-1 | 8.9 | I-2 | 2.7 | W-4 | 0.0083 |
| 14-4 | liquid 10 | | | | | | | | | |
| Example | Dispersion | 52 | M-2 | 9.6 | B-1 | 4.45 | I-2 | 2.7 | W-4 | 0.0083 |
| 15-4 | liquid 10 | | | | B-2 | 4.45 | | | | |
| Example | Dispersion | 52 | M-2 | 9.6 | B-2 | 8.9 | I-3 | 2.7 | W-4 | 0.0083 |
| 16-4 | liquid 10 | | | | | | | | | |
| Example | Dispersion | 52 | M-2 | 9.6 | B-2 | 8.9 | I-2 | 2.6 | W-4 | 0.0083 |
| 17-4 | liquid 10 | | | | | | I-3 | 0.1 | | |

TABLE 9

| | Additive | | Solvent | | Cyclic siloxane compound | | |
|---|---|---|---|---|---|---|---|
| | | Blending | | Blending | | Blending | |
| | | amount | | amount | | amount | Proportion of cyclic |
| | | (part by | | (part by | | (part by | siloxane compound |
| | Type | mass) | Type | mass) | Type | mass) | (part by mass) |
| Example 1-4 | | | S-1 | 23.6 | Sil-3 | 0.25 | 0.3 |
| Example 2-4 | | | S-1 | 23.6 | Sil-3 | 0.25 | 0.3 |
| Example 3-4 | | | S-1 | 23.6 | Sil-3 | 0.25 | 0.3 |
| Example 4-4 | | | S-1 | 23.6 | Sil-3 | 0.25 | 0.3 |
| Example 5-4 | | | S-1 | 23.6 | Sil-3 | 0.25 | 0.3 |
| Example 6-4 | | | S-1 | 23.6 | Sil-3 | 0.25 | 0.3 |
| Example 7-4 | | | S-1 | 23.6 | Sil-3 | 0.25 | 0.3 |
| Example 8-4 | | | S-1 | 23.6 | Sil-3 | 0.25 | 0.3 |
| Example 9-4 | | | S-1 | 23.6 | Sil-3 | 0.25 | 0.3 |
| Example 10-4 | A-1 | 0.25 | S-1 | 11.8 | Sil-3 | 0.25 | 0.3 |
| | A-2 | 2.5 | S-2 | 11.9 | | | |
| Example 11-4 | | | S-1 | 23.6 | Sil-3 | 0.25 | 0.3 |
| Example 12-4 | A-1 | 0.25 | S-1 | 11.8 | Sil-3 | 0.25 | 0.3 |
| | A-2 | 2.5 | S-2 | 11.9 | | | |
| Example 13-4 | A-1 | 0.25 | S-1 | 11.8 | Sil-3 | 0.25 | 0.3 |
| | A-2 | 2.5 | S-2 | 11.9 | | | |
| Example 14-4 | A-1 | 0.25 | S-1 | 11.8 | Sil-3 | 0.25 | 0.3 |
| | A-2 | 2.5 | S-2 | 11.9 | | | |
| Example 15-4 | A-1 | 0.25 | S-1 | 11.8 | Sil-3 | 0.25 | 0.3 |
| | A-2 | 2.5 | S-2 | 11.9 | | | |
| Example 16-4 | A-1 | 0.25 | S-1 | 11.8 | Sil-3 | 0.25 | 0.3 |
| | A-2 | 2.5 | S-2 | 11.9 | | | |
| Example 17-4 | A-1 | 0.25 | S-1 | 11.8 | Sil-3 | 0.25 | 0.3 |
| | A-2 | 2.5 | S-2 | 11.9 | | | |

TABLE 10

| | | | Polymerizable | | | | Photopolymerization | | | |
|---|---|---|---|---|---|---|---|---|---|---|
| | Dispersion liquid | | monomer | | Resin | | initiator | | Surfactant | |
| | | Blending | | Blending | | Blending | | Blending | | Blending |
| | | amount | | amount | | amount | | amount | | amount |
| | | (part by | | (part by | | (part by | | (part by | | (part by |
| | Type | mass) | Type | mass) | Type | mass) | Type | mass) | Type | mass) |
| Example | Dispersion | 65 | M-1 | 3 | B-1 | 7.3 | I-1 | 1.1 | W-5 | 0.0083 |
| 1-5 | liquid 1 | | | | | | | | | |
| Example | Dispersion | 65 | M-1 | 3 | B-1 | 7.3 | I-1 | 1.1 | W-5 | 0.0083 |
| 2-5 | liquid 2 | | | | | | | | | |
| Example | Dispersion | 65 | M-1 | 3 | B-1 | 7.3 | I-1 | 1.1 | W-5 | 0.0083 |
| 3-5 | liquid 3 | | | | | | | | | |
| Example | Dispersion | 65 | M-1 | 3 | B-1 | 7.3 | I-1 | 1.1 | W-5 | 0.0083 |
| 4-5 | liquid 4 | | | | | | | | | |
| Example | Dispersion | 65 | M-1 | 3 | B-1 | 7.3 | I-1 | 1.1 | W-5 | 0.0083 |
| 5-5 | liquid 5 | | | | | | | | | |
| Example | Dispersion | 65 | M-1 | 3 | B-1 | 7.3 | I-1 | 1.1 | W-5 | 0.0083 |
| 6-5 | liquid 6 | | | | | | | | | |
| Example | Dispersion | 65 | M-1 | 3 | B-1 | 7.3 | I-1 | 1.1 | W-5 | 0.0083 |
| 7-5 | liquid 7 | | | | | | | | | |
| Example | Dispersion | 65 | M-1 | 3 | B-1 | 7.3 | I-1 | 1.1 | W-5 | 0.0083 |
| 8-5 | liquid 8 | | | | | | | | | |
| Example | Dispersion | 65 | M-1 | 3 | B-1 | 7.3 | I-1 | 1.1 | W-5 | 0.0083 |
| 9-5 | liquid 9 | | | | | | | | | |
| Example | Dispersion | 52 | M-2 | 9.6 | B-2 | 8.9 | I-2 | 2.7 | W-5 | 0.0083 |
| 10-5 | liquid 10 | | | | | | | | | |
| Example | Dispersion | 65 | M-1 | 3 | B-1 | 7.3 | I-1 | 1.1 | W-5 | 0.0083 |
| 11-5 | liquid 11 | | | | | | | | | |
| Example | Dispersion | 52 | M-1 | 9.6 | B-2 | 8.9 | I-2 | 2.7 | W-5 | 0.0083 |
| 12-5 | liquid 10 | | | | | | | | | |
| Example | Dispersion | 52 | M-1 | 4.8 | B-2 | 8.9 | I-2 | 2.7 | W-5 | 0.0083 |
| 13-5 | liquid 10 | | M-2 | 4.8 | | | | | | |
| Example | Dispersion | 52 | M-2 | 9.6 | B-1 | 8.9 | I-2 | 2.7 | W-5 | 0.0083 |
| 14-5 | liquid 10 | | | | | | | | | |
| Example | Dispersion | 52 | M-2 | 9.6 | B-1 | 4.45 | I-2 | 2.7 | W-5 | 0.0083 |
| 15-5 | liquid 10 | | | | B-2 | 4.45 | | | | |
| Example | Dispersion | 52 | M-2 | 9.6 | B-2 | 8.9 | I-3 | 2.7 | W-5 | 0.0083 |
| 16-5 | liquid 10 | | | | | | | | | |
| Example | Dispersion | 52 | M-2 | 9.6 | B-2 | 8.9 | I-2 | 2.6 | W-5 | 0.0083 |
| 17-5 | liquid 10 | | | | | | I-3 | 0.1 | | |

TABLE 11

| | | | | | Cyclic siloxane | | |
|---|---|---|---|---|---|---|---|
| | Additive | | Solvent | | compound | | |
| | | Blending | | Blending | | Blending | |
| | | amount | | amount | | amount | Proportion of cyclic |
| | | (part by | | (part by | | (part by | siloxane compound |
| | Type | mass) | Type | mass) | Type | mass) | (part by mass) |
| Example | | | S-1 | 23.6 | Sil-1 | 0.84 | 5 |
| 1-5 | | | | | Sil-2 | 2.52 | |
| | | | | | Sil-3 | 0.84 | |
| Example | | | S-1 | 23.6 | Sil-1 | 0.84 | 5 |
| 2-5 | | | | | Sil-2 | 2.52 | |
| | | | | | Sil-3 | 0.84 | |
| Example | | | S-1 | 23.6 | Sil-1 | 0.84 | 5 |
| 3-5 | | | | | Sil-2 | 2.52 | |
| | | | | | Sil-3 | 0.84 | |
| Example | | | S-1 | 23.6 | Sil-1 | 0.84 | 5 |
| 4-5 | | | | | Sil-2 | 2.52 | |
| | | | | | Sil-3 | 0.84 | |
| Example | | | S-1 | 23.6 | Sil-1 | 0.84 | 5 |
| 5-5 | | | | | Sil-2 | 2.52 | |
| | | | | | Sil-3 | 0.84 | |
| Example | | | S-1 | 23.6 | Sil-1 | 0.84 | 5 |
| 6-5 | | | | | Sil-2 | 2.52 | |
| | | | | | Sil-3 | 0.84 | |
| Example | | | S-1 | 23.6 | Sil-1 | 0.84 | 5 |
| 7-5 | | | | | Sil-2 | 2.52 | |
| | | | | | Sil-3 | 0.84 | |
| Example | | | S-1 | 23.6 | Sil-1 | 0.84 | 5 |
| 8-5 | | | | | Sil-2 | 2.52 | |
| | | | | | Sil-3 | 0.84 | |
| Example | | | S-1 | 23.6 | Sil-1 | 0.84 | 5 |
| 9-5 | | | | | Sil-2 | 2.52 | |
| | | | | | Sil-3 | 0.84 | |
| Example | A-1 | 0.25 | S-1 | 11.8 | Sil-1 | 0.84 | 5 |
| 10-5 | A-2 | 2.5 | S-2 | 11.9 | Sil-2 | 2.52 | |
| | | | | | Sil-3 | 0.84 | |
| Example | | | S-1 | 23.6 | Sil-1 | 0.84 | 5 |
| 11-5 | | | | | Sil-2 | 2.52 | |
| | | | | | Sil-3 | 0.84 | |
| Example | A-1 | 0.25 | S-1 | 11.8 | Sil-1 | 0.84 | 5 |
| 12-5 | A-2 | 2.5 | S-2 | 11.9 | Sil-2 | 2.52 | |
| | | | | | Sil-3 | 0.84 | |
| Example | A-1 | 0.25 | S-1 | 11.8 | Sil-1 | 0.84 | 5 |
| 13-5 | A-2 | 2.5 | S-2 | 11.9 | Sil-2 | 2.52 | |
| | | | | | Sil-3 | 0.84 | |
| Example | A-1 | 0.25 | S-1 | 11.8 | Sil-1 | 0.84 | 5 |
| 14-5 | A-2 | 2.5 | S-2 | 11.9 | Sil-2 | 2.52 | |
| | | | | | Sil-3 | 0.84 | |
| Example | A-1 | 0.25 | S-1 | 11.8 | Sil-1 | 0.84 | 5 |
| 15-5 | A-2 | 2.5 | S-2 | 11.9 | Sil-2 | 2.52 | |
| | | | | | Sil-3 | 0.84 | |
| Example | A-1 | 0.25 | S-1 | 11.8 | Sil-1 | 0.84 | 5 |
| 16-5 | A-2 | 2.5 | S-2 | 11.9 | Sil-2 | 2.52 | |
| | | | | | Sil-3 | 0.84 | |
| Example | A-1 | 0.25 | S-1 | 11.8 | Sil-1 | 0.84 | 5 |
| 17-5 | A-2 | 2.5 | S-2 | 11.9 | Sil-2 | 2.52 | |
| | | | | | Sil-3 | 0.84 | |

TABLE 12

| | | | Polymerizable | | | | Photopolymerization | | | |
|---|---|---|---|---|---|---|---|---|---|---|
| | Dispersion liquid | | monomer | | Resin | | initiator | | Surfactant | |
| | | Blending | | Blending | | Blending | | Blending | | Blending |
| | | amount | | amount | | amount | | amount | | amount |
| | | (part by | | (part by | | (part by | | (part by | | (part by |
| | Type | mass) | Type | mass) | Type | mass) | Type | mass) | Type | mass) |
| Example | Dispersion | 65 | M-1 | 3 | B-1 | 7.3 | I-1 | 1.1 | W-6 | 0.0083 |
| 1-6 | liquid 1 | | | | | | | | | |
| Example | Dispersion | 65 | M-1 | 3 | B-1 | 7.3 | I-1 | 1.1 | W-6 | 0.0083 |
| 2-6 | liquid 2 | | | | | | | | | |
| Example | Dispersion | 65 | M-1 | 3 | B-1 | 7.3 | I-1 | 1.1 | W-6 | 0.0083 |
| 3-6 | liquid 3 | | | | | | | | | |
| Example | Dispersion | 65 | M-1 | 3 | B-1 | 7.3 | I-1 | 1.1 | W-6 | 0.0083 |
| 4-6 | liquid 4 | | | | | | | | | |
| Example | Dispersion | 65 | M-1 | 3 | B-1 | 7.3 | I-1 | 1.1 | W- | 0.0083 |
| 5-6 | liquid 5 | | | | | | | | | |
| Example | Dispersion | 65 | M-1 | 3 | B-1 | 7.3 | I-1 | 1.1 | W-6 | 0.0083 |
| 6-6 | liquid 6 | | | | | | | | | |
| Example | Dispersion | 65 | M-1 | 3 | B-1 | 7.3 | I-1 | 1.1 | W-6 | 0.0083 |
| 7-6 | liquid 7 | | | | | | | | | |
| Example | Dispersion | 65 | M-1 | 3 | B-1 | 7.3 | I-1 | 1.1 | W-6 | 0.0083 |
| 8-6 | liquid 8 | | | | | | | | | |
| Example | Dispersion | 65 | M-1 | 3 | B-1 | 7.3 | I-1 | 1.1 | W-6 | 0.0083 |
| 9-6 | liquid 9 | | | | | | | | | |
| Example | Dispersion | 52 | M-2 | 9.6 | B-2 | 8.9 | I-2 | 2.7 | N-6 | 0.0083 |
| 10-6 | liquid 10 | | | | | | | | | |
| Example | Dispersion | 65 | M-1 | 3 | B-1 | 7.3 | I-1 | 1.1 | W-6 | 0.0083 |
| 11-6 | liquid 11 | | | | | | | | | |
| Example | Dispersion | 52 | M-1 | 9.6 | B-2 | 8.9 | I-2 | 2.7 | W- | 0.0083 |
| 12-6 | liquid 10 | | | | | | | | | |
| Example | Dispersion | 52 | M-1 | 4.8 | B-2 | 8.9 | I-2 | 2.7 | W-6 | 0.0083 |
| 13-6 | liquid 10 | | M-2 | 4.8 | | | | | | |
| Example | Dispersion | 52 | M-2 | 9.6 | B-1 | 8.9 | I-2 | 2.7 | W-6 | 0.0083 |
| 14-6 | liquid 10 | | | | | | | | | |
| Example | Dispersion | 52 | M-2 | 9.6 | B-1 | 4.45 | I-2 | 2.7 | W-6 | 0.0083 |
| 15-6 | liquid 10 | | | | B-2 | 4.45 | | | | |
| Example | Dispersion | 52 | M-2 | 9.6 | B-2 | 8.9 | I-3 | 2.7 | W-6 | 0.0083 |
| 16-6 | liquid 10 | | | | | | | | | |
| Example | Dispersion | 52 | M-2 | 9.6 | B-2 | 8.9 | I-2 | 2.6 | W-6 | 0.0083 |
| 17-6 | liquid 10 | | | | | | I-3 | 0.1 | | |

TABLE 13

| | | | | | Cyclic siloxane | | |
|---|---|---|---|---|---|---|---|
| | Additive | | Solvent | | compound | | |
| | | Blending | | Blending | | Blending | |
| | | amount | | amount | | amount | Proportion of cyclic |
| | | (part by | | (part by | | (part by | siloxane compound |
| | Type | mass) | Type | mass) | Type | mass) | (part by mass) |
| Example 1-6 | | | S-1 | 23.6 | Sil-1 | 0.8 | 1 |
| Example 2-6 | | | S-1 | 23.6 | Sil-1 | 0.8 | 1 |
| Example 3-6 | | | S-1 | 23.6 | Sil-1 | 0.8 | 1 |
| Example 4-6 | | | S-1 | 23.6 | Sil-1 | 0.8 | 1 |
| Example 5-6 | | | S-1 | 23.6 | Sil-1 | 0.8 | 1 |
| Example 6-6 | | | S-1 | 23.6 | Sil-1 | 0.8 | 1 |
| Example 7-6 | | | S-1 | 23.6 | Sil-1 | 0.8 | 1 |
| Example 8-6 | | | S-1 | 23.6 | Sil-1 | 0.8 | 1 |
| Example 9-6 | | | S-1 | 23.6 | Sil-1 | 0.8 | 1 |
| Example | A-1 | 0.25 | S-1 | 11.8 | Sil-1 | 0.8 | 1 |
| 10-6 | A-2 | 2.5 | S-2 | 11.9 | | | |
| Example | | | S-1 | 23.6 | Sil-1 | 0.8 | 1 |
| 11-6 | | | | | | | |
| Example | A-1 | 0.25 | S-1 | 11.8 | Sil-1 | 0.8 | 1 |
| 12-6 | A-2 | 2.5 | S-2 | 11.9 | | | |
| Example | A-1 | 0.25 | S-1 | 11.8 | Sil-1 | 0.8 | 1 |
| 13-6 | A-2 | 2.5 | S-2 | 11.9 | | | |
| Example | A-1 | 0.25 | S-1 | 11.8 | Sil-1 | 0.8 | 1 |
| 14-6 | A-2 | 2.5 | S-2 | 11.9 | | | |
| Example | A-1 | 0.25 | S-1 | 11.8 | Sil-1 | 0.8 | 1 |
| 15-6 | A-2 | 2.5 | S-2 | 11.9 | | | |
| Example | A-1 | 0.25 | S-1 | 11.8 | Sil-1 | 0.8 | 1 |
| 16-6 | A-2 | 2.5 | S-2 | 11.9 | | | |
| Example | A-1 | 0.25 | S-1 | 11.8 | Sil-1 | 0.8 | 1 |
| 17-6 | A-2 | 2.5 | S-2 | 11.9 | | | |

TABLE 14

| | | | Polymerizable | | | | Photopolymerization | | | |
|---|---|---|---|---|---|---|---|---|---|---|
| | Dispersion liquid | | monomer | | Resin | | initiator | | Surfactant | |
| | | Blending | | Blending | | Blending | | Blending | | Blending |
| | | amount | | amount | | amount | | amount | | amount |
| | | (part by | | (part by | | (part by | | (part by | | (part by |
| | Type | mass) | Type | mass) | Type | mass) | Type | mass) | Type | mass) |
| Comparative | Dispersion | 65 | M-1 | 3 | B-1 | 7.3 | I-1 | 1.1 | CW-1 | 0.0083 |
| Example 1-1 | liquid 1 | | | | | | | | | |
| Comparative | Dispersion | 65 | M-1 | 3 | B-1 | 7.3 | I-1 | 1.1 | CW-1 | 0.0083 |
| Example 2-1 | liquid 2 | | | | | | | | | |
| Comparative | Dispersion | 65 | M-1 | 3 | B-1 | 7.3 | I-1 | 1.1 | W-6 | 0.0083 |
| Example 1-2 | liquid 1 | | | | | | | | | |
| Comparative | Dispersion | 65 | M-1 | 3 | B-1 | 7.3 | I-1 | 1.1 | W-6 | 0.0083 |
| Example 2-2 | liquid 2 | | | | | | | | | |

TABLE 15

| | | | | | Cyclic siloxane | | |
|---|---|---|---|---|---|---|---|
| | Additive | | Solvent | | compound | | |
| | | Blending | | Blending | | Blending | |
| | | amount | | amount | | amount | Proportion of cyclic |
| | | (part by | | (part by | | (part by | siloxane compound |
| | Type | mass) | Type | mass) | Type | mass) | (part by mass) |
| Comparative | | | S-1 | 23.6 | — | — | — |
| Example 1-1 | | | | | | | |
| Comparative | | | S-1 | 23.6 | — | — | — |
| Example 2-1 | | | | | | | |
| Comparative | | | S-1 | 23.6 | Sil-1 | 12.45 | 15 |
| Example 1-2 | | | | | | | |
| Comparative | | | S-1 | 23.6 | Sil-1 | 12.45 | 15 |
| Example 2-2 | | | | | | | |

Among the raw materials listed in the above tables, details of the raw materials shown by abbreviations are as follows.

### [Dispersion Liquid]

Dispersion liquids 1 to 11: dispersion liquids 1 to 11 described above

### [Polymerizable Monomer]

M-1: KAYARAD DPHA (manufactured by Nippon Kayaku Co., Ltd., mixture of dipentaerythritol hexaacrylate and dipentaerythritol pentaacrylate)

M-2: compound having the following structure

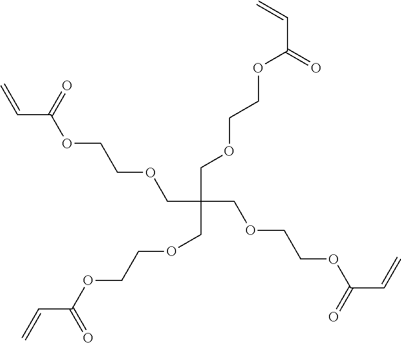 [SMILES: C=CC(=O)OCCOCC(COCCOC(=O)C=C)(COCCOC(=O)C=C)COCCOC(=O)C=C]

### [Resin]

B-1: resin having the following structure (a numerical value added to a main chain represents a molar ratio; weight-average molecular weight: 11,000)

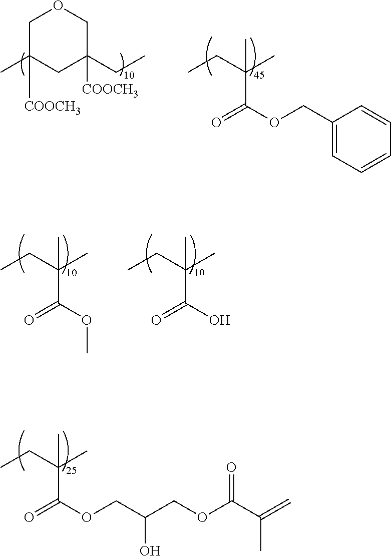

B-2: resin having the following structure (a numerical value added to a main chain represents a molar ratio; weight-average molecular weight: 11,000)

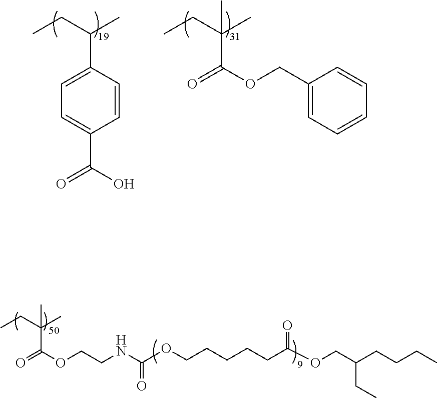

### [Photopolymerization Initiator]

I-1: Irgacure OXE01 (oxime compound, manufactured by BASF SE)
I-2: compound having the following structure
I-3: compound having the following structure

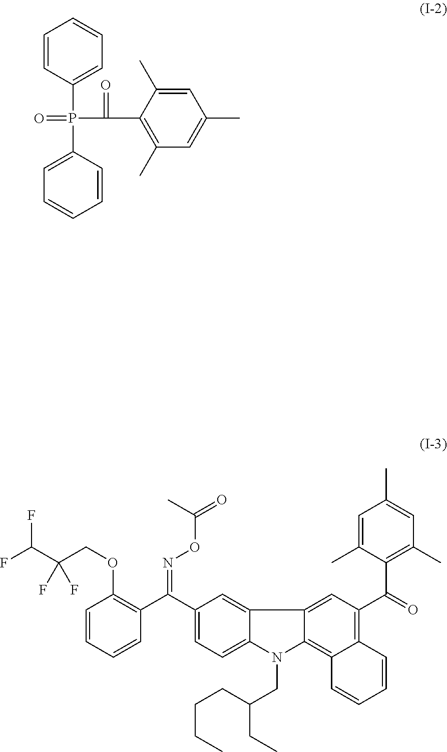 [SMILES: Cc1cc(C)c(C(=O)P(=O)(c2ccccc2)c2ccccc2)c(C)c1 ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

### [Surfactant]

W-1: compound having the following structure (hydroxyl number: 120 mgKOH/g, silicone-based surfactant)

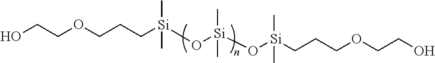

W-2: FZ-2122 (manufactured by Dow-TORAY, silicone-based surfactant)

W-3: SH 8400 FLUID (manufactured by Dow-TORAY, silicone-based surfactant, compound having the following structure)

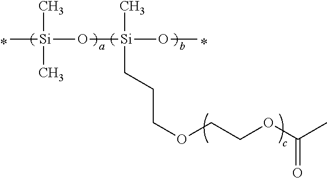

W-4: compound having the following structure (hydroxyl number: 62 mgKOH/g, silicone-based surfactant)

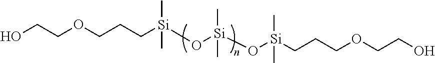

W-5: compound having the following structure (hydroxyl number: 35 mgKOH/g, silicone-based surfactant)

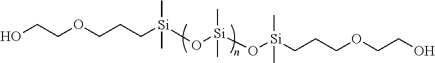

W-6: BYK-330 (manufactured by BYK Chemie, silicone-based surfactant)

CW-1: FTERGENT 710FM (manufactured by NEOS COMPANY LIMITED, fluorine-based surfactant)

### [Cyclic Siloxane Compound]

Sil-1: octamethylcyclotetrasiloxane
Sil-2: decamethylcyclopentasiloxane
Sil-3: dodecamethylcyclohexasiloxane

### [Additive]

A-1: compound having the following structure (antioxidant)

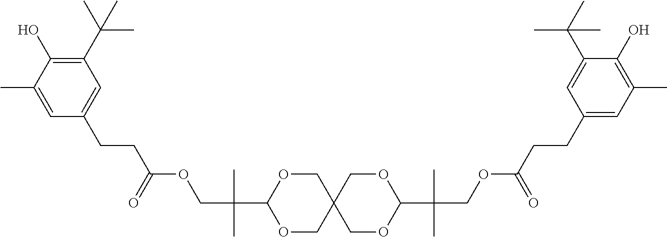

A-2: compound having the following structure (silane coupling agent)

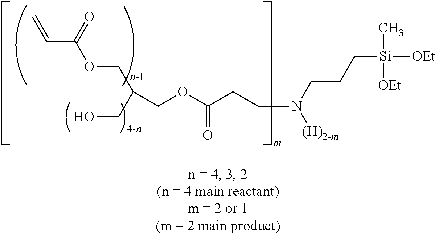

### [Solvent]

S-1: propylene glycol monomethyl ether acetate

S-2: propylene glycol monomethyl ether

### <Evaluation of Reliability>

A composition for forming a base layer (CT-4000L, manufactured by Fujifilm Electronic Materials Co., Ltd.) was applied onto a glass wafer with a diameter of 8 inches (20.32 cm) so that a dry film thickness was 0.1 m, dried, and then heated at 220° C. for 5 minutes to form a base layer.

Next, each composition was applied onto the glass wafer on which the base layer had been formed using a spin coater such that a film thickness after pre-baking was 0.6 m, and a heating treatment (pre-baking) was performed for 120 seconds using a hot plate at 100° C. Next, using an i-ray stepper exposure device (FPA-3000 i5+, manufactured by Canon Inc.), the entire surface of the glass wafer was irradiated with light having a wavelength of 365 nm to perform exposure thereon with an exposure amount of 500 mJ/cm². The glass wafer having the film after the exposure was subjected to a heating treatment (post-baking) for 300 seconds using a hot plate at 200° C., thereby forming a film. Using a spectrometer (U-4150, manufactured by Hitachi High-Tech Corporation), a transmittance of the glass wafer on which the film had been formed was measured in a wavelength range of 400 to 1100 nm.

Next, the above-described glass wafer on which the film had been formed was placed in a constant-temperature tank at a temperature of 85° C. and a relative humidity of 85% for 2000 hours to perform a reliability test. Using a spectrometer (U-4150, manufactured by Hitachi High-Tech Corporation), a transmittance of the above-described glass wafer after the reliability test, on which the film had been formed, was measured in the wavelength range of 400 to 1100 nm.

In Examples 1-1 to 8-1, 1-2 to 8-2, 1-3 to 8-3, 1-4 to 8-4, 1-5 to 8-5, and 1-6 to 8-6, and Comparative Examples 1-1, 1-2, 2-1, and 2-2, the maximum value of a difference in transmittance of the film before and after the reliability test was evaluated, and reliability was evaluated according to the following standard.

Difference in transmittance=|Transmittance of film before reliability test−Transmittance of film after reliability test|
5: maximum value of the difference in transmittance was 1% or less.
4: maximum value of the difference in transmittance was more than 1% and 1.5% or less.
3: maximum value of the difference in transmittance was more than 1.5% and 2% or less.
2: maximum value of the difference in transmittance was more than 2% and 3% or less.
1: maximum value of the difference in transmittance was more than 3%.

In Examples 9-1 to 17-1, 9-2 to 17-2, 9-3 to 17-3, 9-4 to 17-4, 9-5 to 17-5, and 9-6 to 17-6, a spectral variation rate was evaluated based on the transmittance before the reliability test, and reliability was evaluated according to the following standard.

The evaluation was carried out with Spectral variation rate=(1−Transmittance of film after reliability test/Transmittance of film before reliability)×100.
5: maximum value of the spectral variation rate was 1% or less.
4: maximum value of the spectral variation rate was more than 1% and 2% or less.
3: maximum value of the spectral variation rate was more than 2% and 3% or less.
2: maximum value of the spectral variation rate was more than 3% and 4% or less.
1: maximum value of the spectral variation rate was more than 4%.

TABLE 16

| | Evaluation | | Evaluation | | Evaluation |
|---|---|---|---|---|---|
| Example | 5 | Example | 4 | Example | 4 |
| 1-1 | | 1-2 | | 1-3 | |
| Example | 5 | Example | 4 | Example | 4 |
| 2-1 | | 2-2 | | 2-3 | |
| Example | 5 | Example | 4 | Example | 4 |
| 3-1 | | 3-2 | | 3-3 | |
| Example | 5 | Example | 4 | Example | 4 |
| 4-1 | | 4-2 | | 4-3 | |
| Example | 5 | Example | 4 | Example | 4 |
| 5-1 | | 5-2 | | 5-3 | |
| Example | 5 | Example | 4 | Example | 4 |
| 6-1 | | 6-2 | | 6-3 | |
| Example | 5 | Example | 4 | Example | 4 |
| 7-1 | | 7-2 | | 7-3 | |
| Example | 5 | Example | 4 | Example | 4 |
| 8-1 | | 8-2 | | 8-3 | |
| Example | 5 | Example | 4 | Example | 4 |
| 9-1 | | 9-2 | | 9-3 | |
| Example | 5 | Example | 4 | Example | 4 |
| 10-1 | | 10-2 | | 10-3 | |
| Example | 5 | Example | 4 | Example | 4 |
| 11-1 | | 11-2 | | 11-3 | |
| Example | 5 | Example | 4 | Example | 4 |
| 12-1 | | 12-2 | | 12-3 | |
| Example | 5 | Example | 4 | Example | 4 |
| 13-1 | | 13-2 | | 13-3 | |
| Example | 5 | Example | 4 | Example | 4 |
| 14-1 | | 14-2 | | 14-3 | |
| Example | 5 | Example | 4 | Example | 4 |
| 15-1 | | 15-2 | | 15-3 | |
| Example | 5 | Example | 4 | Example | 4 |
| 16-1 | | 16-2 | | 16-3 | |
| Example | 5 | Example | 4 | Example | 4 |
| 17-1 | | 17-2 | | 17-3 | |

TABLE 17

| | Evaluation | | Evaluation | | Evaluation | | Evaluation |
|---|---|---|---|---|---|---|---|
| Example 1-4 | 3 | Example 1-5 | 2 | Example 1-6 | 4 | Comparative | 1 |
| | | | | | | Example 1-1 | |
| Example 2-4 | 3 | Example 2-5 | 2 | Example 2-6 | 4 | Comparative | 1 |
| | | | | | | Example 2-1 | |
| Example 3-4 | 3 | Example 3-5 | 2 | Example 3-6 | 4 | Comparative | 1 |
| | | | | | | Example 1-2 | |
| Example 4-4 | 3 | Example 4-5 | 2 | Example 4-6 | 4 | Comparative | 1 |
| | | | | | | Example 2-2 | |
| Example 5-4 | 3 | Example 5-5 | 2 | Example 5-6 | 4 | | |
| Example 6-4 | 3 | Example 6-5 | 2 | Example 6-6 | 4 | | |
| Example 7-4 | 3 | Example 7-5 | 2 | Example 7-6 | 4 | | |
| Example 8-4 | 3 | Example 8-5 | 2 | Example 8-6 | 4 | | |
| Example 9-4 | 3 | Example 9-5 | 2 | Example 9-6 | 4 | | |
| Example 10-4 | 3 | Example 10-5 | 2 | Example 10-6 | 4 | | |
| Example 11-4 | 3 | Example 11-5 | 2 | Example 11-6 | 4 | | |
| Example 12-4 | 3 | Example 12-5 | 2 | Example 12-6 | 4 | | |
| Example 13-4 | 3 | Example 13-5 | 2 | Example 13-6 | 4 | | |
| Example 14-4 | 3 | Example 14-5 | 2 | Example 14-6 | 4 | | |
| Example 15-4 | 3 | Example 15-5 | 2 | Example 15-6 | 4 | | |
| Example 16-4 | 3 | Example 16-5 | 2 | Example 16-6 | 4 | | |
| Example 17-4 | 3 | Example 17-5 | 2 | Example 17-6 | 4 | | |

As shown in the above tables, Examples were all excellent in the evaluation of reliability as compared with Comparative Examples. The same effects could be obtained even in a case where two or more kinds of surfactants were used.

What is claimed is:

1. A composition comprising:
a cyclic siloxane compound;
a silicone-based surfactant other than the cyclic siloxane compound; and
a curable compound,
wherein a content of the cyclic siloxane compound is 0.01 to 10 parts by mass with respect to 100 parts by mass of the silicone-based surfactant.

2. The composition according to claim 1,
wherein the cyclic siloxane compound is a compound represented by Formula (1), 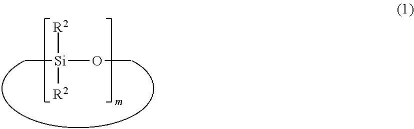
in Formula (1), R¹ and R² each independently represent a hydrogen atom or a substituent, and m represents an integer of 3 to 20.

3. The composition according to claim 1,
wherein the cyclic siloxane compound includes at least one selected from octamethylcyclotetrasiloxane, decamethylcyclopentasiloxane, or dodecamethylcyclohexasiloxane.

4. A composition comprising:
a cyclic siloxane compound;
a silicone-based surfactant other than the cyclic siloxane compound; and
a curable compound,
wherein the cyclic siloxane compound is at least one selected from octamethylcyclotetrasiloxane, decamethylcyclopentasiloxane, or dodecamethylcyclohexasiloxane, and
a content of the cyclic siloxane compound is 0.01 to 10 parts by mass with respect to 100 parts by mass of the silicone-based surfactant.

5. The composition according to claim 1,
wherein the composition contains two or more kinds of the cyclic siloxane compounds.

6. The composition according to claim 1,
wherein a content of the silicone-based surfactant in the composition is 1 to 2,000 ppm by mass.

7. The composition according to claim 1,
wherein the curable compound contains a resin and a polymerizable monomer, and the composition further contains a photopolymerization initiator.

8. The composition according to claim 1, further comprising:
a coloring material.

9. A film formed of the composition according to claim 1.

10. An optical filter comprising:
the film according to claim 9.

11. An optical sensor comprising:
the film according to claim 9.

12. An image display device comprising:
the film according to claim 9.
